(19) United States
(12) Patent Application Publication
(10) Pub. No.: US 2024/0422913 A1
(43) Pub. Date: Dec. 19, 2024

(54) CIRCUIT MODULE AND CIRCUIT BOARD

(71) Applicant: Murata Manufacturing Co., Ltd., Nagaokakyo-shi (JP)

(72) Inventor: Ryutatsu MIZUKAMI, Nagaokakyo-shi (JP)

(73) Assignee: Murata Manufacturing Co., Ltd., Nagaokakyo-shi (JP)

(21) Appl. No.: 18/811,804

(22) Filed: Aug. 22, 2024

Related U.S. Application Data
(63) Continuation of application No. PCT/JP2023/002848, filed on Jan. 30, 2023.

(30) Foreign Application Priority Data
Mar. 1, 2022 (JP) 2022-031132
May 31, 2022 (JP) 2022-088297

(51) Int. Cl. H05K 1/14; H05K 1/11

(52) U.S. Cl. CPC H05K 1/144; H05K 1/111; H05K 2201/09381

(57) ABSTRACT

In a circuit module, a first signal electrode is electrically connected to a first signal conductor layer. A first branch electrode is electrically connected to a first branch conductor layer. A second signal electrode is electrically connected to a second signal conductor layer and is bonded to the first signal electrode by using a conductive bonding material. A second branch electrode is electrically connected to a second ground conductor layer and is bonded to the first branch electrode by using a conductive bonding material.

### CROSS-REFERENCE TO RELATED APPLICATIONS

This application is a continuation of international application no. PCT/JP2023/002848, filed Jan. 30, 2023, and which claims the benefit of priority to Japanese application no. 2022-031132, filed Mar. 1, 2022, and to Japanese application no. 2022-088297, filed May 31, 2022. The entire contents of all prior applications are hereby incorporate by reference.

### TECHNICAL FIELD

The present disclosure relates to a circuit module including a first circuit board and a second circuit board.

### BACKGROUND ART

As the invention related to a circuit module in the related art, for example, a transmission line device is known. The transmission line device includes a first multilayer substrate and a second multilayer substrate. The first multilayer substrate and the second multilayer substrate are fixed by using solder.

### SUMMARY

### Technical Problem

In the field of the transmission line device described above, there is a demand for suppressing a deviation of a characteristic impedance generated at a connection portion between the first multilayer substrate and the second multilayer substrate from a desired characteristic impedance (for example, 50 Q).

Therefore, the present disclosure provides a circuit module and a circuit board which can suppress a deviation of a characteristic impedance generated at a connection portion between a first circuit board and a second circuit board from a desired characteristic impedance.

### Solution to Problem

An aspect of the present disclosure relates to a circuit module including a first circuit board, and one or more circuit boards, in which the one or more circuit boards have a portion overlapping the first circuit board when viewed in an up-down direction. The first circuit board includes a first board body having a first upper main surface and a first lower main surface. A first signal conductor layer is provided in the first board body. A first branch conductor layer is provided in the first board body and electrically connected to the first signal conductor layer. A first signal electrode is located on the first lower main surface, and a first branch electrode is located on the first upper main surface or the first lower main surface. The one or more circuit boards include one or more board bodies having an upper main surface and a lower main surface. A second signal conductor layer is provided in any one of the one or more board bodies. A second ground conductor layer is provided in any one of the one or more board bodies. A second signal electrode is located on the upper main surface of the board body provided with the second signal conductor layer among the one or more board bodies, and a second branch electrode is located on the upper main surface or the lower main surface of the board body provided with the second ground conductor layer among the one or more board bodies. The first signal electrode is electrically connected to the first signal conductor layer, and the first branch electrode is electrically connected to the first branch conductor layer. The second signal electrode is electrically connected to the second signal conductor layer and is bonded to the first signal electrode by using a conductive bonding material, and the second branch electrode is electrically connected to the second ground conductor layer and is bonded to the first branch electrode by using a conductive bonding material.

Another aspect of the present disclosure relates to a circuit module including a first circuit board, and one or more circuit boards, in which the one or more circuit boards have a portion overlapping the first circuit board when viewed in an up-down direction. The first circuit board includes a first board body having a first upper main surface and a first lower main surface. A first signal conductor layer is provided in the first board body. A first branch conductor is layer provided in the first board body and electrically connected to the first signal conductor layer. A first signal electrode is located on the first lower main surface, and a first branch electrode is located on the first upper main surface or the first lower main surface. The one or more circuit boards include one or more board bodies having an upper main surface and a lower main surface. A second radiation conductor layer transmits or receives electromagnetic waves and is provided in any one of the one or more board bodies. A second ground conductor layer is provided in any one of the one or more board bodies. A second signal electrode is located on the upper main surface of the board body provided with the second radiation conductor layer among the one or more board bodies. A second branch electrode is located on the upper main surface or the lower main surface of the board body provided with the second ground conductor layer among the one or more board bodies. The first signal electrode is electrically connected to the first signal conductor layer, the first branch electrode is electrically connected to the first branch conductor layer, and the second signal electrode is electrically connected to the second radiation conductor layer and is bonded to the first signal electrode by using a conductive bonding material. The second branch electrode is electrically connected to the second ground conductor layer and is bonded to the first branch electrode by using a conductive bonding material.

Still another aspect of the present disclosure relates to a first circuit board including a first board body having a first upper main surface and a first lower main surface, and a first signal conductor layer provided in the first board body. A first branch conductor layer is provided in the first board body and electrically connected to the first signal conductor layer. A first signal electrode is located on the first lower main surface. A first branch electrode located on the first upper main surface or the first lower main surface, in which the first signal electrode is electrically connected to the first signal conductor layer. The first branch electrode is electrically connected to the first branch conductor layer and, when the first circuit board is connected to one or more circuit boards, is connected to a ground potential by being bonded to a second branch electrode of the one or more circuit boards by using a conductive bonding material.

### Advantageous Effects

With the circuit module according to the present disclosure, it is possible to suppress the deviation of the characteristic impedance generated at the connection portion between the first circuit board and the second circuit board from the desired characteristic impedance.

### BRIEF DESCRIPTION OF DRAWINGS

FIG. 1 is a cross-sectional view of a circuit module 1.

FIG. 2 is a rear view of the circuit module 1 in use.

FIG. 3 is a rear view of the circuit module 1 in use.

FIG. 4 is a cross-sectional view of a circuit board 510.

FIG. 5 is a top view of a first signal conductor layer 18, a first branch conductor layer 19, a first signal electrode 32, a first branch electrode 34, and a third ground electrode 36a of a circuit module 1a.

FIG. 6 is a top view of the first signal conductor layer 18, the first branch conductor layer 19, the first signal electrode 32, the first branch electrode 34, and the third ground electrode 36a of a circuit module 1b.

FIG. 7 is a top view of the first signal conductor layer 18, the first branch conductor layer 19, the first signal electrode 32, the first branch electrode 34, the third ground electrode 36a, and a fourth ground electrode 36b of a circuit module 1c.

FIG. 8 is a top view of the first signal conductor layer 18, the first branch conductor layer 19, the first signal electrode 32, the first branch electrode 34, the third ground electrode 36a, and the fourth ground electrode 36b of a circuit module 1d.

FIG. 9 is a top view of the first signal conductor layer 18, the first branch conductor layer 19, an open stub conductor layer 70a, the first signal electrode 32, and the first branch electrode 34 of a circuit module 1e.

FIG. 10 is a top view of the first signal conductor layer 18, the first branch conductor layer 19, open stub conductor layers 70a and 70b, the first signal electrode 32, and the first branch electrode 34 of a circuit module 1f.

FIG. 11 is a top view of the first signal conductor layer 18, the first branch conductor layer 19, a second branch conductor layer 72a, the first signal electrode 32, the first branch electrode 34, and a third branch electrode 38a of a circuit module 1g.

FIG. 12 is a cross-sectional view taken along a line A-A in FIG. 11.

FIG. 13 is a top view of the first signal conductor layer 18, the first branch conductor layer 19, second branch conductor layers 72a and 72b, the first signal electrode 32, the first branch electrode 34, and third branch electrodes 38a and 38b of a circuit module 1h.

FIG. 14 is a top view of the first signal conductor layer 18, the first branch conductor layer 19, the first signal electrode 32, and the first branch electrode 34 of a circuit module 1i.

FIG. 15 is a cross-sectional view of a circuit module 1j.

FIG. 16 is a cross-sectional view of a circuit module 1k.

FIG. 17 is a cross-sectional view of a circuit module 1l.

FIG. 18 is a cross-sectional view of a circuit module 1m.

FIG. 19 is a cross-sectional view of a circuit module 1n.

FIG. 20 is a cross-sectional view of a circuit module 1o.

FIG. 21 is a cross-sectional view of a circuit module 1p.

FIG. 22 is a cross-sectional view of a circuit module 1q.

FIG. 23 is a cross-sectional view of a circuit module 1r.

FIG. 24 is a cross-sectional view of a circuit module 1s.

FIG. 25 is a cross-sectional view of a circuit module 1t.

### DESCRIPTION OF EMBODIMENTS

### Embodiment

### [Structure of Circuit Module 1]

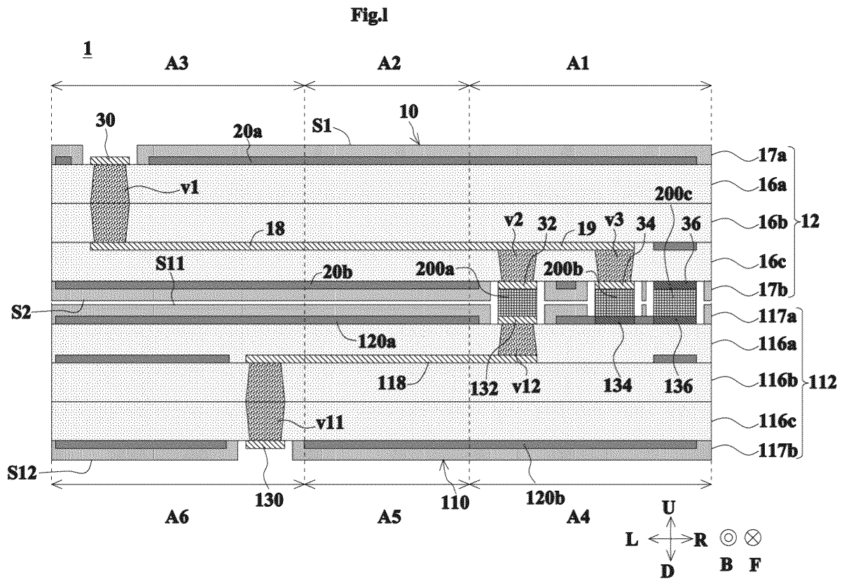

Hereinafter, a structure of a circuit module 1 according to an exemplary embodiment of the present disclosure will be described with reference to the accompanying drawings. FIG. 1 is a cross-sectional view of the circuit module 1.

In the present specification, directions are defined as follows. A direction in which a first circuit board 10 and a second circuit board 110 are arranged is an up-down direction. A direction in which a first signal conductor layer 18 extends is a left-right direction. The left-right direction is orthogonal to the up-down direction. A front-rear direction is orthogonal to the up-down direction and the left-right direction. The up-down direction, the front-rear direction, and the left-right direction in the present specification need not match the up-down direction, the front-rear direction, and the left-right direction of the circuit module 1 in actual use. The front direction and the rear direction may be interchanged, the left direction and the right direction may be interchanged, or the up direction and the down direction may be interchanged.

First, the structure of the circuit module 1 will be described with reference to FIG. 1. The circuit module 1 is used in electronic equipment such as a smartphone. The circuit module 1 includes the first circuit board 10, the second circuit board 110, and conductive bonding materials 200a to 200c.

First, a structure of the first circuit board 10 will be described. The first circuit board 10 includes a first board body 12, the first signal conductor layer 18, a first branch conductor layer 19, a third ground conductor layer 20a, a first ground conductor layer 20b, an upper surface signal electrode 30, a first signal electrode 32, a first branch electrode 34, a first ground electrode 36, and interlayer connection conductors v1 to v3.

The first board body 12 has a plate shape. The first board body 12 has a first upper main surface S1 and a first lower main surface S2. The first board body 12 has a structure in which a plurality of first dielectric layers 16a to 16c, a protective layer 17a, and a first protective layer 17b are laminated in the up-down direction. The first dielectric layers 16a to 16c are arranged in this order from top to bottom. The first dielectric layers 16a to 16c are dielectric sheets having flexibility. Materials of the first dielectric layers 16a to 16c are resins. In the present exemplary embodiment, the materials of the first dielectric layers 16a to 16c are thermoplastic resins. The thermoplastic resin is, for example, a liquid crystal polymer or polytetrafluoroethylene (PTFE). The materials of the first dielectric layers 16a to 16c may be polyimide. Among the first dielectric layers 16a to 16c, the first dielectric layers adjacent in the up-down direction are welded to each other. Such a first board body 12 has flexibility. The protective layer 17a and the first protective layer 17b will be described later.

The first signal conductor layer 18 is provided in the first board body 12. In the present exemplary embodiment, the first signal conductor layer 18 is located on a lower main surface of the first dielectric layer 16b. The first signal conductor layer 18 has a linear shape extending in the left-right direction. A high frequency signal is transmitted through the first signal conductor layer 18.

The first branch conductor layer 19 is provided in the first board body 12. In the present exemplary embodiment, the first branch conductor layer 19 is located on the lower main surface of the first dielectric layer 16b. The first branch conductor layer 19 is electrically connected to the first signal conductor layer 18. More specifically, the first branch conductor layer 19 has a linear shape. The first branch conductor layer 19 extends from a right end of the first signal conductor layer 18 in the right direction. In the present specification, a starting point of the first branch conductor layer 19 is a portion branching from a main path of the high frequency signal. The main path of the high frequency signal is a path that is connected to the first signal electrode 32 from the first signal conductor layer 18 via the interlayer connection conductor v2. The starting point of the first branch conductor layer 19 is a portion branching from the first signal conductor layer 18. In the present exemplary embodiment, the starting point of the first branch conductor layer 19 is the center of the interlayer connection conductor v2 when viewed in the up-down direction. On the other hand, an end point of the first branch conductor layer 19 is the center of the interlayer connection conductor v3.

The third ground conductor layer 20a is provided in the first board body 12. In the present exemplary embodiment, the third ground conductor layer 20a is located on an upper main surface of the first dielectric layer 16a. As a result, the third ground conductor layer 20a is located above the first signal conductor layer 18. The third ground conductor layer 20a overlaps the first signal conductor layer 18 and the first branch conductor layer 19 when viewed in the up-down direction. Further, the third ground conductor layer 20a overlaps the first signal electrode 32, the first branch electrode 34, and the first ground electrode 36, which will be described later, when viewed in the up-down direction.

The first ground conductor layer 20b is provided in the first board body 12. In the present exemplary embodiment, the first ground conductor layer 20b is located on a lower main surface of the first dielectric layer 16c. As a result, the first ground conductor layer 20b is located below the first signal conductor layer 18. The first ground conductor layer 20b overlaps the first signal conductor layer 18 and the first branch conductor layer 19 when viewed in the up-down direction. In addition, the first ground conductor layer 20b is electrically connected to the third ground conductor layer 20a with an interlayer connection conductor (not illustrated) interposed therebetween. The first signal conductor layer 18, the third ground conductor layer 20a, and the first ground conductor layer 20b as described above have a stripline structure as described above.

The upper surface signal electrode 30 is located on the first upper main surface S1. In the present exemplary embodiment, the upper surface signal electrode 30 is located on the upper main surface of the first dielectric layer 16a. The upper surface signal electrode 30 is electrically connected to the first signal conductor layer 18. Specifically, the upper surface signal electrode 30 overlaps a left end portion of the first signal conductor layer 18 when viewed in the up-down direction. The interlayer connection conductor v1 penetrates the first dielectric layers 16a and 16b in the up-down direction. The interlayer connection conductor v1 electrically connects the upper surface signal electrode 30 and the left end portion of the first signal conductor layer 18. As a result, the high frequency signal is input and output through the upper surface signal electrode 30.

The first signal electrode 32 is located on the first lower main surface S2. In the present exemplary embodiment, the first signal electrode 32 is located on the lower main surface of the first dielectric layer 16c. The first signal electrode 32 is electrically connected to the first signal conductor layer 18. Specifically, the first signal electrode 32 overlaps the right end portion of the first signal conductor layer 18 when viewed in the up-down direction. The interlayer connection conductor v2 penetrates the first dielectric layer 16c in the up-down direction. The interlayer connection conductor v2 electrically connects the first signal electrode 32 and the right end portion of the first signal conductor layer 18. As a result, the high frequency signal is input and output through the first signal electrode 32.

The first branch electrode 34 is located on the first lower main surface S2. In the present exemplary embodiment, the first branch electrode 34 is located on the lower main surface of the first dielectric layer 16c. The first branch electrode 34 is electrically connected to the first branch conductor layer 19. Specifically, the first branch electrode 34 overlaps a right end portion of the first branch conductor layer 19 when viewed in the up-down direction. The interlayer connection conductor v3 penetrates the first dielectric layer 16c in the up-down direction. The interlayer connection conductor v3 electrically connects the first branch electrode 34 and the right end portion of the first branch conductor layer 19. The first branch electrode 34 is not electrically connected to any ground conductor layer in a state in which the first circuit board 10 and the second circuit board 110 are not connected.

The first ground electrode 36 is located on the first lower main surface S2. In the present exemplary embodiment, the first ground electrode 36 is located on the lower main surface of the first dielectric layer 16c. The first ground electrode 36 is electrically connected to the first ground conductor layer 20b. In the present exemplary embodiment, the first ground electrode 36 and the first ground conductor layer 20b form one conductor layer.

As described above, the first signal conductor layer 18, the first branch conductor layer 19, the third ground conductor layer 20a, the first ground conductor layer 20b, the upper surface signal electrode 30, the first signal electrode 32, the first branch electrode 34, and the first ground electrode 36 are formed by sticking a metal foil on the upper main surface or the lower main surface of the first dielectric layer 16a to 16c and patterning the metal foil by a photolithography process. The metal foil is, for example, a copper foil.

In addition, the interlayer connection conductors v1 to v3 are formed by filling through-holes penetrating the first dielectric layers 16a to 16c in the up-down direction with a conductive paste and solidifying the conductive paste by heating. However, the interlayer connection conductors v1 to v3 may be formed by subjecting the through-holes to plating.

The protective layer 17a is laminated at an uppermost part in the first board body 12. The protective layer 17a covers the third ground conductor layer 20a. However, the upper surface signal electrode 30 is exposed to an outside of the first board body 12 through an opening provided in the protective layer 17a.

The first protective layer 17b is laminated at a lowermost part in the first board body 12. The first protective layer 17b covers the first ground conductor layer 20b. However, the first signal electrode 32, the first branch electrode 34, and the first ground electrode 36 are exposed to the outside of the first board body 12 through an opening provided in the first protective layer 17b. The protective layer 17a and the first protective layer 17b as described above are dielectric layers. The protective layer 17a and the first protective layer 17b may be formed by printing, or may be formed by attaching a resin sheet.

Next, a structure of the second circuit board 110 will be described. The second circuit board 110 is located below the first circuit board 10, and has a portion overlapping the first circuit board 10 when viewed in the up-down direction. The second circuit board 110 includes a second board body 112, a second signal conductor layer 118, a second ground conductor layer 120a, a ground conductor layer 120b, a lower surface signal electrode 130, a second signal electrode 132, a second branch electrode 134, a second ground electrode 136, and interlayer connection conductors v11 and v12.

The second board body 112 has a plate shape. The second board body 112 has a second upper main surface S11 and a second lower main surface S12. The second board body 112 has a structure in which a plurality of second dielectric layers 116a to 116c, a second protective layer 117a, and a protective layer 117b are laminated in the up-down direction. The second dielectric layers 116a to 116c are arranged in this order from top to bottom. The second dielectric layers 116a to 116c are dielectric sheets having flexibility. Materials of the second dielectric layers 116a to 116c are resins. In the present exemplary embodiment, the materials of the second dielectric layers 116a to 116c are thermoplastic resins. The thermoplastic resin is, for example, a liquid crystal polymer or polytetrafluoroethylene (PTFE). The materials of the second dielectric layers 116a to 116c may be polyimide. Among the second dielectric layers 116a to 116c, the second dielectric layers adjacent in the up-down direction are welded to each other. Such a second board body 112 has flexibility. The second protective layer 117a and the protective layer 117b will be described later.

The second signal conductor layer 118 is provided in the second board body 112. In the present exemplary embodiment, the second signal conductor layer 118 is located on an upper main surface of the second dielectric layer 116b. The second signal conductor layer 118 has a linear shape extending in the left-right direction. The high frequency signal is transmitted to the second signal conductor layer 118.

The second ground conductor layer 120a is provided in the second board body 112. In the present exemplary embodiment, the second ground conductor layer 120a is located on an upper main surface of the second dielectric layer 116a. As a result, the second ground conductor layer 120a is located above the second signal conductor layer 118. The second ground conductor layer 120a overlaps the second signal conductor layer 118 when viewed in the up-down direction.

The ground conductor layer 120b is provided in the second board body 112. In the present exemplary embodiment, the ground conductor layer 120b is located on a lower main surface of the second dielectric layer 116c. As a result, the ground conductor layer 120b is located below the second signal conductor layer 118. The ground conductor layer 120b overlaps the second signal conductor layer 118 when viewed in the up-down direction. In addition, the ground conductor layer 120b is electrically connected to the second ground conductor layer 120a with an interlayer connection conductor (not illustrated) interposed therebetween. The second signal conductor layer 118, the second ground conductor layer 120a, and the ground conductor layer 120b have a stripline structure.

The lower surface signal electrode 130 is located on the second lower main surface S12. In the present exemplary embodiment, the lower surface signal electrode 130 is located on the lower main surface of the second dielectric layer 116c. The lower surface signal electrode 130 is electrically connected to the second signal conductor layer 118. The lower surface signal electrode 130 overlaps a left end portion of the second signal conductor layer 118 when viewed in the up-down direction. The interlayer connection conductor v11 penetrates the second dielectric layers 116b and 116c in the up-down direction. The interlayer connection conductor v11 electrically connects the lower surface signal electrode 130 and the left end portion of the second signal conductor layer 118. As a result, the high frequency signal is input and output through the lower surface signal electrode 130.

The second signal electrode 132 is located on the second upper main surface S11. In the present exemplary embodiment, the second signal electrode 132 is located on the upper main surface of the second dielectric layer 116a. The second signal electrode 132 is electrically connected to the second signal conductor layer 118. Specifically, the second signal electrode 132 overlaps a right end portion of the second signal conductor layer 118 when viewed in the up-down direction. The interlayer connection conductor v12 penetrates the second dielectric layer 116a in the up-down direction. The interlayer connection conductor v12 electrically connects the second signal electrode 132 and the right end portion of the second signal conductor layer 118. As a result, the high frequency signal is input and output through the second signal electrode 132.

The second branch electrode 134 is located on the second upper main surface S11. In the present exemplary embodiment, the second branch electrode 134 is located on the upper main surface of the second dielectric layer 116a. The second branch electrode 134 is electrically connected to the second ground conductor layer 120a.

The second ground electrode 136 is located on the second upper main surface S11. In the present exemplary embodiment, the second ground electrode 136 is located on the upper main surface of the second dielectric layer 116a. The second ground electrode 136 is electrically connected to the second ground conductor layer 120a. In the present exemplary embodiment, the second ground electrode 136, the second ground conductor layer 120a, the second branch electrode 134 form one conductor layer.

As described above, the second signal conductor layer 118, the second ground conductor layer 120a, the ground conductor layer 120b, the lower surface signal electrode 130, the second signal electrode 132, the second branch electrode 134, and the second ground electrode 136 are formed by sticking a metal foil on the upper main surface or the lower main surface of the second dielectric layers 116a to 116c and patterning the metal foil by a photolithography process. The metal foil is, for example, a copper foil.

In addition, the interlayer connection conductors v11 and v12 are formed by filling through-holes penetrating the second dielectric layers 116a to 116c in the up-down direction with a conductive paste and solidifying the conductive paste by heating. However, the interlayer connection conductors v11 and v12 may be formed by subjecting the through-holes to plating.

The second protective layer 117a is laminated at an uppermost part in the second board body 112. The second protective layer 117a covers the second ground conductor layer 120a. However, the second signal electrode 132, the second branch electrode 134, and the second ground electrode 136 are exposed to an outside of the second board body 112 through an opening provided in the second protective layer 117a.

The protective layer 117b is laminated at a lowermost part in the second board body 112. The protective layer 117b covers the ground conductor layer 120b. However, the lower surface signal electrode 130 is exposed to the outside of the second board body 112 through an opening provided in the protective layer 117b. The second protective layer 117a and the protective layer 117b as described above are dielectric layers. The second protective layer 117a and the protective layer 117b may be formed by printing, or may be formed by attaching a resin sheet.

The second circuit board 110 as described above is connected to the first circuit board 10. More specifically, the second signal electrode 132 is bonded to the first signal electrode 32 by using the conductive bonding material 200a. As a result, the second signal conductor layer 118 is electrically connected to the first signal conductor layer 18. In addition, the second branch electrode 134 is bonded to the first branch electrode 34 by using the conductive bonding material 200b. The second branch electrode 134 is electrically connected to the second ground conductor layer 120a. Therefore, when the first circuit board 10 is connected to the second circuit board 110, the first branch electrode 34 is connected to a ground potential by being bonded to the second branch electrode 134 of the second circuit board 110 by using the conductive bonding material 200b. In addition, the second ground electrode 136 is bonded to the first ground electrode 36 by using the conductive bonding material 200c. As a result, the second ground conductor layer 120a is electrically connected to the first ground conductor layer 20b. The conductive bonding materials 200a, 200b, and 200c are, for example, solder. However, the conductive bonding materials 200a, 200b, and 200c may be, for example, a conductive adhesive in which metal powder is dispersed in a resin.

However, the second circuit board 110 is fixed to the first circuit board 10 only by using the conductive adhesive including the conductive bonding materials 200a and 200b. Therefore, the second circuit board 110 is not fixed to the first circuit board 10 in a portion other than the conductive adhesive. That is, the second protective layer 117a is not fixed to the first protective layer 17b.

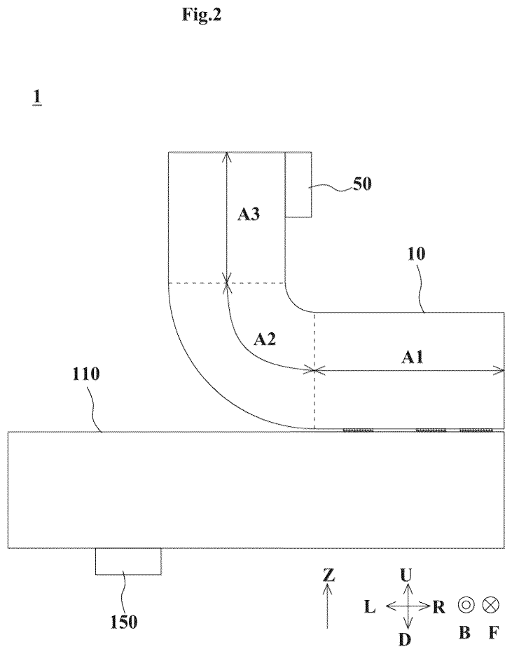

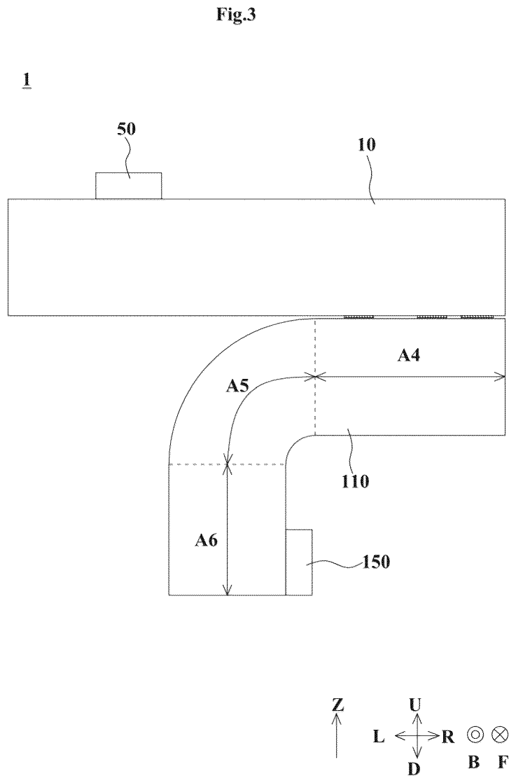

Next, a usage aspect of the circuit module 1 will be described. FIGS. 2 and 3 are rear views of the circuit module 1 in use.

As illustrated in FIG. 2, a connector 50 is mounted in the upper surface signal electrode 30 of the first circuit board 10. A connector 150 is mounted in the lower surface signal electrode 130 of the second circuit board 110. In addition, when the circuit module 1 is used, the first board body 12 of the first circuit board 10 is bent. Hereinafter, a detailed description thereof will be made.

As illustrated in FIGS. 1 and 2, the first board body 12 has a first section A1, a second section A2, and a third section A3. The first section A1, the second section A2, and the third section A3 are arranged in this order from right to left. The first signal electrode 32, the first branch electrode 34, and the first ground electrode 36 are located in the first section A1. The connector 50 is located in the third section A3.

The up-down direction in the first section A1 is defined as a Z-axis direction. A positive direction of the Z-axis is an up direction in the first section A1. A negative direction of the Z-axis is a down direction in the first section A1. In this case, the second section A2 is bent in the Z-axis direction with respect to the first section A1. In the present exemplary embodiment, the second section A2 is bent with respect to the first section A1 in the positive direction of the Z-axis. The first section A1 and the third section A3 are not bent. However, the first section A1 and the third section A3 may be bent. In this case, a curvature radius of the first section A1 and a curvature radius of the third section A3 are larger than a curvature radius of the second section A2.

In addition, when the circuit module 1 is used, the second board body 112 of the second circuit board 110 may be bent. Hereinafter, a detailed description thereof will be made.

As illustrated in FIGS. 1 and 3, the second board body 112 has a fourth section A4, a fifth section A5, and a sixth section A6. The fourth section A4, the fifth section A5, and the sixth section A6 are arranged in this order from right to left. The second signal electrode 132, the second branch electrode 134, and the second ground electrode 136 are located in the fourth section A4. The connector 150 is located in the sixth section A6.

The up-down direction in the fourth section A4 is defined as the Z-axis direction. A positive direction of the Z-axis is an up direction in the fourth section A4. A negative direction of the Z-axis is a down direction in the fourth section A4. In this case, the fifth section A5 is bent in the Z-axis direction with respect to the fourth section A4. In the present exemplary embodiment, the fifth section A5 is bent in the negative direction of the Z-axis with respect to the fourth section A4. The fourth section A4 and the sixth section A6 are not bent. However, the fourth section A4 and the sixth section A6 may be bent. In this case, a curvature radius of the fourth section A4 and a curvature radius of the sixth section A6 are larger than a curvature radius of the fifth section A5.

### [Effects]

(a) With the circuit module 1, it is possible to suppress a deviation of a characteristic impedance generated at a connection portion between the first circuit board 10 and the second circuit board 110 from a desired characteristic impedance. More specifically, the first signal electrode 32, the second signal electrode 132, the interlayer connection conductors v2 and v12, and the conductive bonding material 200a are present in the connection portion between the first circuit board 10 and the second circuit board 110. Therefore, a structure of the connection portion between the first circuit board 10 and the second circuit board 110 is significantly different from a structure of the first signal conductor layer 18 and a structure of the second signal conductor layer 118. Therefore, the characteristic impedance generated at the connection portion between the first circuit board 10 and the second circuit board 110 is likely to be different from a characteristic impedance generated at the first signal conductor layer 18 and a characteristic impedance generated at the second signal conductor layer 118.

Therefore, in the circuit module 1, a short stub is provided in the first circuit board 10. The short stub matches the characteristic impedance generated at the connection portion between the first circuit board 10 and the second circuit board 110 with the characteristic impedance generated at the first signal conductor layer 18 and the characteristic impedance generated at the second signal conductor layer 118. More specifically, the first branch conductor layer 19 is electrically connected to the first signal conductor layer 18. Further, the first branch conductor layer 19 is electrically connected to the second ground conductor layer 120a connected to the ground potential, with the first branch electrode 34, the second branch electrode 134, and the conductive bonding material 200a interposed therebetween. As a result, the first branch conductor layer 19 functions as the short stub. As a result, the first branch conductor layer 19 matches the characteristic impedance generated at the connection portion between the first circuit board 10 and the second circuit board 110 with the characteristic impedance generated at the first signal conductor layer 18 and the characteristic impedance generated at the second signal conductor layer 118. As described above, with the circuit module 1, it is possible to suppress the deviation of the characteristic impedance generated at the connection portion between the first circuit board 10 and the second circuit board 110 from the desired characteristic impedance.

A length of the short stub is designed such that the short stub can match the characteristic impedance generated at the connection portion between the first circuit board 10 and the second circuit board 110 with the characteristic impedance generated at the first signal conductor layer 18 and the characteristic impedance generated at the second signal conductor layer 118. Such a length of the short stub is, for example, equal to or less than a wavelength of the high frequency signal.

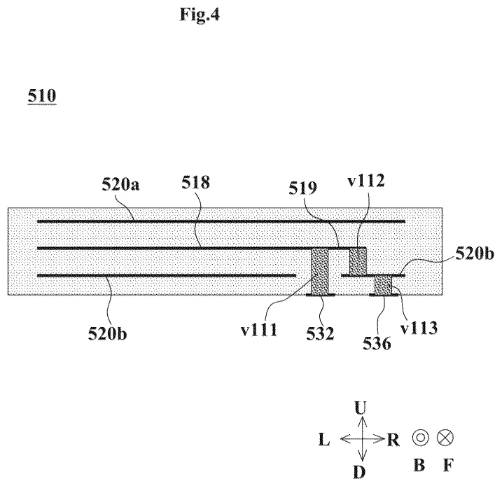

(b) With the circuit module 1, it is easy to detect the short of the first circuit board 10. Hereinafter, a circuit board 510 according to a comparative example will be described as an example. FIG. 4 is a cross-sectional view of the circuit board 510.

The circuit board 510 includes a signal conductor layer 518, a branch conductor layer 519, ground conductor layers 520a and 520b, a signal electrode 532, a ground electrode 536, and interlayer connection conductors v111 to v113. The signal conductor layer 518 and the ground conductor layers 520a and 520b have a stripline structure. The interlayer connection conductor v111 electrically connects a right end portion of the signal conductor layer 518 and the signal electrode 532.

The branch conductor layer 519 extends from the right end of the signal conductor layer 518 in the right direction. The interlayer connection conductor v112 electrically connects a right end portion of the branch conductor layer 519 and the ground conductor layer 520b. The interlayer connection conductor v113 electrically connects the ground conductor layer 520b and the ground electrode 536. As described above, the circuit board 510 does not include a branch electrode. Therefore, the branch conductor layer 519 is electrically connected to the ground conductor layer 520b in the circuit board 510.

In such a circuit board 510, it is difficult to detect the short between the signal conductor layer 518 and the ground conductor layer 520b.

Therefore, in the circuit module 1, the first branch electrode 34 is electrically connected to the first branch conductor layer 19. The first branch electrode 34 is not in contact with the first ground conductor layer 20b. As a result, the first branch electrode 34 is not electrically connected to any ground conductor layer in a state in which the first circuit board 10 and the second circuit board 110 are not connected. Therefore, it is possible to detect the short between the first signal conductor layer 18 and the first ground conductor layer 20b and the short between the first signal conductor layer 18 and the third ground conductor layer 20a in a state in which the first circuit board 10 and the second circuit board 110 are not connected. As described above, with the circuit module 1, it is easy to detect the short of the first circuit board 10.

(c) In the circuit module 1, the first signal conductor layer 18, the third ground conductor layer 20a, and the first ground conductor layer 20b have a stripline structure. As a result, it is easy to make the characteristic impedance generated at the first signal conductor layer 18 close to the desired characteristic impedance (for example, 50Ω).

(d) In the circuit module 1, it is possible to suppress the deviation of the characteristic impedance generated at the connection portion between the first circuit board 10 and the second circuit board 110 from the desired characteristic impedance. More specifically, the first signal electrode 32 and the first branch electrode 34 are exposed to the outside of the first board body 12 through the opening provided in the first protective layer 17b. The second signal electrode 132 and the second branch electrode 134 are exposed to the outside of the second board body 112 through the opening provided in the second protective layer 117a. As a result, a shape of the conductive bonding material 200a is determined by shapes of the two openings, a thickness of the first protective layer 17b in the up-down direction, and a thickness of the second protective layer 117a in the up-down direction. Therefore, a variation in the shape of the conductive bonding material 200a is suppressed, and a variation in the characteristic impedance generated at the conductive bonding material 200a is suppressed. As described above, in the circuit module 1, it is possible to suppress the deviation of the characteristic impedance generated at the connection portion between the first circuit board 10 and the second circuit board 110 from the desired characteristic impedance.

(e) In the circuit module 1, a variation in the characteristic impedance generated at the first signal conductor layer 18 can be suppressed. More specifically, the first circuit board 10 has the second section A2 that is bent in the Z-axis direction with respect to the first section A1. In order to allow the second section A2 to be bent as described above, it is necessary to reduce a thickness of the first board body 12 in the up-down direction. However, in a case where the thickness of the first board body 12 in the up-down direction is reduced, a distance between the first signal conductor layer 18 and the third ground conductor layer 20a, and a distance between the first signal conductor layer 18 and the first ground conductor layer 20b are reduced. As a result, the characteristic impedance generated at the first signal conductor layer 18 is likely to deviate from the desired characteristic impedance. Therefore, the first circuit board 10 is provided with the short stub. As a result, the characteristic impedance generated at the first signal conductor layer 18 can be matched with the desired characteristic impedance.

### First Modification Example

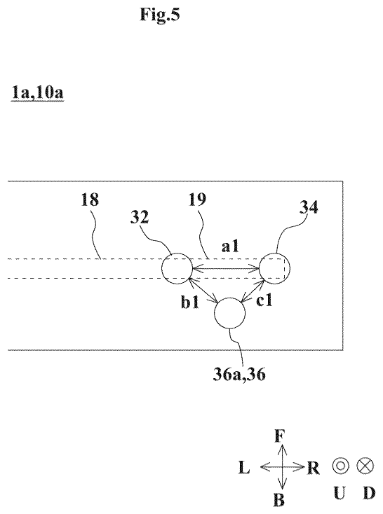

Hereinafter, a circuit module 1a according to a first modification example will be described with reference to the accompanying drawings. FIG. 5 is a top view of the first signal conductor layer 18, the first branch conductor layer 19, the first signal electrode 32, the first branch electrode 34, and a third ground electrode 36a of the circuit module 1a.

A first circuit board 10a of the circuit module 1a may include one or more first ground electrodes 36. The one or more first ground electrodes 36 include the third ground electrode 36a. The first ground electrodes 36 other than the third ground electrode 36a are not illustrated in FIG. 5. Then, when viewed in the up-down direction, a distance a1 between the first signal electrode 32 and the first branch electrode 34 is longer than a distance b1 between the first signal electrode 32 and the third ground electrode 36a, and a distance c1 between the first branch electrode 34 and the third ground electrode 36a (condition 1). The other structures of the circuit module 1a are the same as the structures of the circuit module 1, and thus the description thereof will be omitted. The circuit module 1a can exhibit the effects (a) to (e).

(f) With the circuit module 1a, a leakage of an electromagnetic field between the first signal electrode 32 and the first branch electrode 34 is suppressed. More specifically, when viewed in the up-down direction, the distance a1 between the first signal electrode 32 and the first branch electrode 34 is longer than the distance b1 between the first signal electrode 32 and the third ground electrode 36a, and the distance c1 between the first branch electrode 34 and the third ground electrode 36a. Therefore, in the circuit module 1a, the distance between the first signal electrode 32 and the first branch electrode 34 is long. However, the third ground electrode 36a is located in a vicinity of the first signal electrode 32 and in a vicinity of the first branch electrode 34. The third ground electrode 36a is connected to the ground potential. As a result, the third ground electrode 36a shields between the first signal electrode 32 and the first branch electrode 34. As a result, with the circuit module 1a, the leakage of the electromagnetic field between the first signal electrode 32 and the first branch electrode 34 is suppressed.

### Second Modification Example

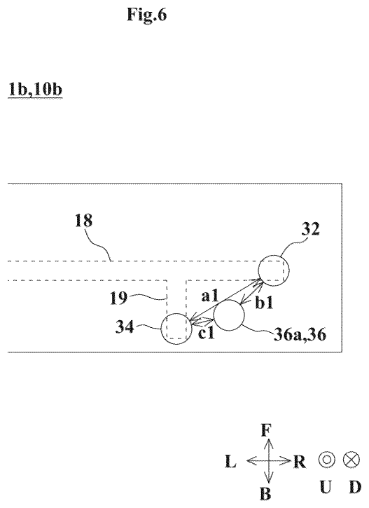

Hereinafter, a circuit module 1b according to a second modification example will be described with reference to the accompanying drawings. FIG. 6 is a top view of the first signal conductor layer 18, the first branch conductor layer 19, the first signal electrode 32, the first branch electrode 34, and the third ground electrode 36a of the circuit module 1b.

In the circuit module 1b, the first branch conductor layer 19 does not extend from the right end of the first signal conductor layer 18 in the right direction. The first branch conductor layer 19 extends in rear direction from between the left end and the right end of the first signal conductor layer 18. That is, the first branch conductor layer 19 has a structure branching from the first signal conductor layer 18. In the circuit module 1b, similarly to the circuit module 1a, when viewed in the up-down direction, the distance a1 between the first signal electrode 32 and the first branch electrode 34 is longer than the distance b1 between the first signal electrode 32 and the third ground electrode 36a, and the distance c1 between the first branch electrode 34 and the third ground electrode 36a. The other structures of the circuit module 1b are the same as the structures of the circuit module 1a, and thus the description thereof will be omitted. The circuit module 1b can exhibit the effects (a) to (f).

### Third Modification Example

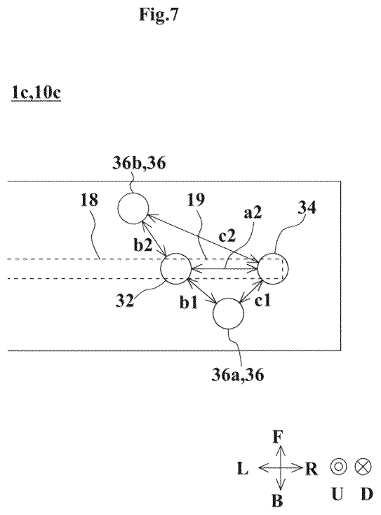

Hereinafter, a circuit module 1c according to a third modification example will be described with reference to the accompanying drawings. FIG. 7 is a top view of the first signal conductor layer 18, the first branch conductor layer 19, the first signal electrode 32, the first branch electrode 34, the third ground electrode 36a, and a fourth ground electrode 36b of the circuit module 1c.

In the circuit module 1c, the one or more first ground electrodes 36 further include the fourth ground electrode 36b. When viewed in the up-down direction, a distance a2 between the first signal electrode 32 and the first branch electrode 34 is shorter than a distance b2 between the first signal electrode 32 and the fourth ground electrode 36b, or a distance c2 between the first branch electrode 34 and the fourth ground electrode 36b. In the present exemplary embodiment, when viewed in the up-down direction, the distance a2 between the first signal electrode 32 and the first branch electrode 34 is longer than the distance b2 between the first signal electrode 32 and the fourth ground electrode 36b. When viewed in the up-down direction, the distance a2 between the first signal electrode 32 and the first branch electrode 34 is shorter than the distance c2 between the first branch electrode 34 and the fourth ground electrode 36b. As described above, in the circuit module 1c, the fourth ground electrode 36b, which does not satisfy the condition 1 satisfied by the circuit module 1a, may be present. The other structures of the circuit module 1c are the same as the structures of the circuit module 1a, and thus the description thereof will be omitted. The circuit module 1c can exhibit the effects (a) to (f).

### Fourth Modification Example

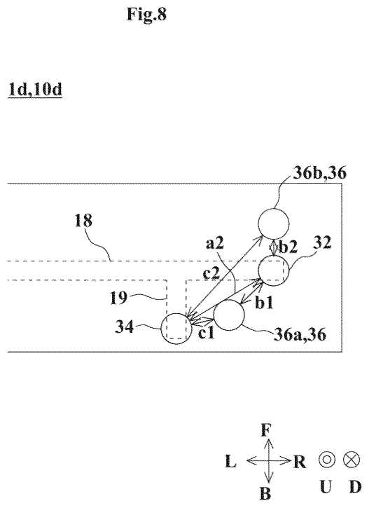

Hereinafter, a circuit module 1d according to a fourth modification example will be described with reference to the accompanying drawings. FIG. 8 is a top view of the first signal conductor layer 18, the first branch conductor layer 19, the first signal electrode 32, the first branch electrode 34, the third ground electrode 36a, and the fourth ground electrode 36b of the circuit module 1d.

The circuit module 1d has the same structure as the circuit module 1b. However, the circuit module 1d further includes the fourth ground electrode 36b in addition to the one or more first ground electrodes 36. When viewed in the up-down direction, the distance a2 between the first signal electrode 32 and the first branch electrode 34 is shorter than the distance b2 between the first signal electrode 32 and the fourth ground electrode 36b, or the distance c2 between the first branch electrode 34 and the fourth ground electrode 36b. In the present exemplary embodiment, when viewed in the up-down direction, the distance a2 between the first signal electrode 32 and the first branch electrode 34 is longer than the distance b2 between the first signal electrode 32 and the fourth ground electrode 36b. When viewed in the up-down direction, the distance a2 between the first signal electrode 32 and the first branch electrode 34 is shorter than the distance c2 between the first branch electrode 34 and the fourth ground electrode 36b. As described above, in the circuit module 1d, the fourth ground electrode 36b, which does not satisfy the condition 1 satisfied by the circuit module 1a, may be present. The other structures of the circuit module 1d are the same as the structures of the circuit module 1b, and thus the description thereof will be omitted. The circuit module 1d can exhibit the effects (a) to (f).

### Fifth Modification Example

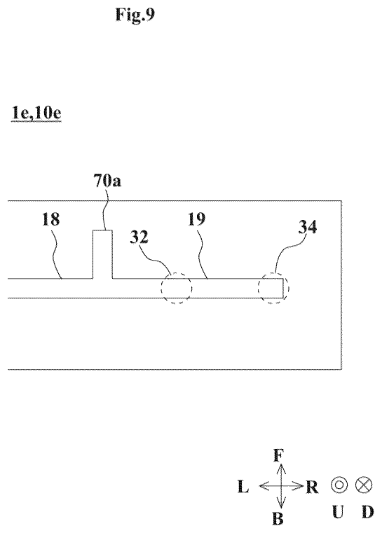

Hereinafter, a circuit module 1e according to a fifth modification example will be described with reference to the accompanying drawings. FIG. 9 is a top view of the first signal conductor layer 18, the first branch conductor layer 19, an open stub conductor layer 70a, the first signal electrode 32, and the first branch electrode 34 of the circuit module 1e.

A first circuit board 10e of the circuit module 1e may further include the open stub conductor layer 70a. The open stub conductor layer 70a is electrically connected to the first signal conductor layer 18 or the first branch conductor layer 19. In the present exemplary embodiment, the open stub conductor layer 70a is in contact with the first signal conductor layer 18. The open stub conductor layer 70a is not electrically connected to an electrode other than an electrode to which the first signal conductor layer 18 is electrically connected. More accurately, the open stub conductor layer 70a is not in contact with the conductor layer other than the first signal conductor layer 18. As a result, a front end of the open stub conductor layer 70a is an open end. The other structures of the circuit module 1e are the same as the structures of the circuit module 1. The circuit module 1e can exhibit the effects (a) to (e).

(g) In the circuit module 1e, the open stub conductor layer 70a functions as an open stub. Therefore, the characteristic impedance generated at the connection portion between the first circuit board 10 and the second circuit board 110 is matched with the characteristic impedance generated at the first signal conductor layer 18 and the characteristic impedance generated at the second signal conductor layer 118.

### Sixth Modification Example

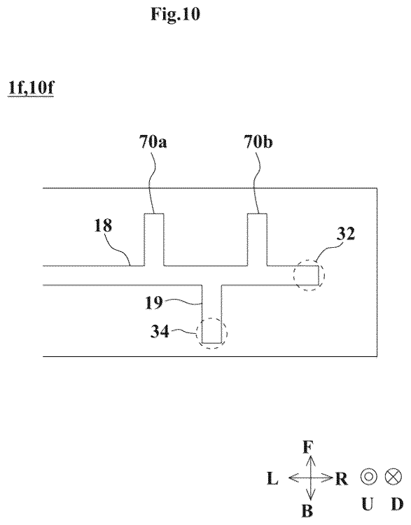

Hereinafter, a circuit module 1f according to a sixth modification example will be described with reference to the accompanying drawings. FIG. 10 is a top view of the first signal conductor layer 18, the first branch conductor layer 19, open stub conductor layers 70a and 70b, the first signal electrode 32, and the first branch electrode 34 of the circuit module 1f.

The circuit module 1f has the same structure as the circuit module 1b. However, a first circuit board 10f of the circuit module 1f further includes the open stub conductor layers 70a and 70b. The open stub conductor layers 70a and 70b are electrically connected to the first signal conductor layer 18 or the first branch conductor layer 19. In the present exemplary embodiment, the open stub conductor layers 70a and 70b are in contact with the first signal conductor layer 18. The open stub conductor layer 70a is in contact with the first signal conductor layer 18 between the left end of the first signal conductor layer 18 and a front end of the first branch conductor layer 19. The open stub conductor layer 70b is in contact with the first signal conductor layer 18 between the right end of the first signal conductor layer 18 and the front end of the first branch conductor layer 19. The open stub conductor layers 70a and 70b are not electrically connected to the electrode other than the electrode to which the first signal conductor layer 18 is electrically connected. More accurately, the open stub conductor layers 70a and 70b are not in contact with the conductor layers other than the first signal conductor layer 18. As a result, front ends of the open stub conductor layers 70a and 70b are open ends. The other structures of the circuit module 1f are the same as the structures of the circuit module 1b. The circuit module 1e can exhibit the effects (a) to (g).

### Seventh Modification Example

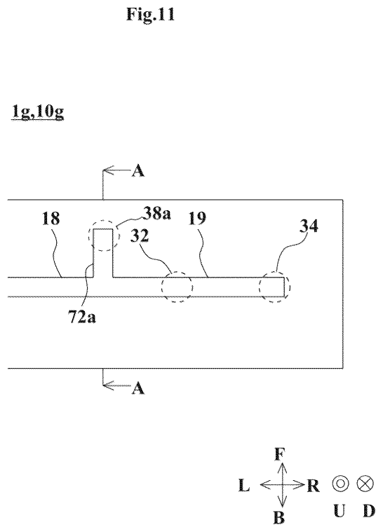

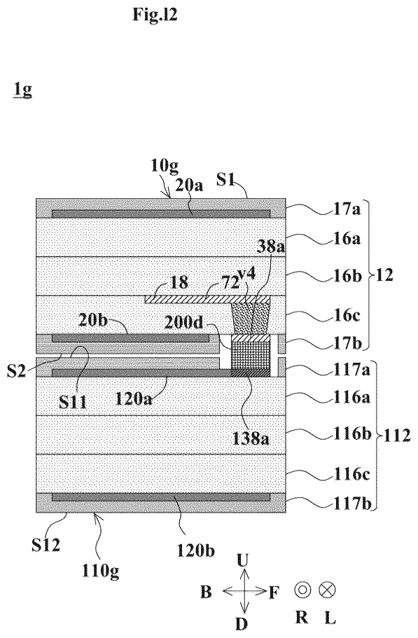

Hereinafter, a circuit module 1g according to a seventh modification example will be described with reference to the accompanying drawings. FIG. 11 is a top view of the first signal conductor layer 18, the first branch conductor layer 19, a second branch conductor layer 72a, the first signal electrode 32, the first branch electrode 34, and a third branch electrode 38a of the circuit module 1g. FIG. 12 is a cross-sectional view taken along a line A-A in FIG. 11.

A first circuit board 10g of the circuit module 1g further includes the second branch conductor layer 72a, the third branch electrode 38a, and an interlayer connection conductor v4. The second branch conductor layer 72a is provided in the first board body 12. The second branch conductor layer 72a is electrically connected to the first signal conductor layer 18. In the present exemplary embodiment, the second branch conductor layer 72a is in contact with the first signal conductor layer 18. The third branch electrode 38a is located on the first lower main surface S2. The third branch electrode 38a is electrically connected to the second branch conductor layer 72a. More specifically, the interlayer connection conductor v4 electrically connects a front end of the second branch conductor layer 72a and the third branch electrode 38a.

A second circuit board 110g of the circuit module 1g further includes a fourth branch electrode 138a. The fourth branch electrode 138a is located on the second upper main surface S11. The fourth branch electrode 138a is electrically connected to the second ground conductor layer 120a. The fourth branch electrode 138a is bonded to the third branch electrode 38a by using a conductive bonding material 200d. The other structures of the circuit module 1g are the same as the structures of the circuit module 1. The circuit module 1g can exhibit the effects (a) to (e).

(h) In the circuit module 1g, the second branch conductor layer 72a functions as a short stub. Therefore, the characteristic impedance generated at the connection portion between the first circuit board 10 and the second circuit board 110 is matched with the characteristic impedance generated at the first signal conductor layer 18 and the characteristic impedance generated at the second signal conductor layer 118.

### Eighth Modification Example

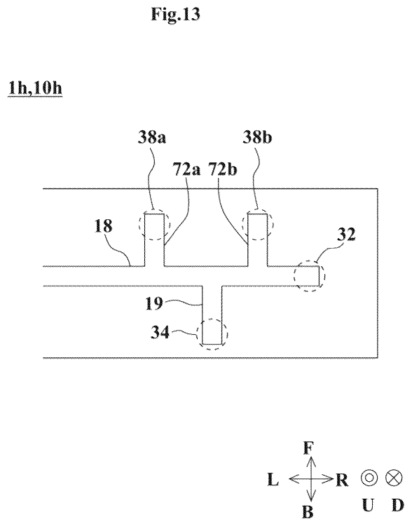

Hereinafter, a circuit module 1h according to an eighth modification example will be described with reference to the accompanying drawings. FIG. 13 is a top view of the first signal conductor layer 18, the first branch conductor layer 19, second branch conductor layers 72a and 72b, the first signal electrode 32, the first branch electrode 34, and third branch electrodes 38a and 38b of the circuit module 1h. A cross-sectional view of the circuit module 1h will be described with reference to FIG. 12.

The circuit module 1h has the same structure as the circuit module 1b. However, a first circuit board 10h of the circuit module 1h further includes the second branch conductor layers 72a and 72b, the third branch electrode 38a and 38b, and interlayer connection conductors v4 and v5. The second branch conductor layers 72a and 72b are electrically connected to the first signal conductor layer 18. The second branch conductor layer 72a is in contact with the first signal conductor layer 18 between the left end of the first signal conductor layer 18 and the front end of the first branch conductor layer 19. The second branch conductor layer 72b is in contact with the first signal conductor layer 18 between the right end of the first signal conductor layer 18 and the front end of the first branch conductor layer 19. A starting point of the second branch conductor layer 72b is a portion branching from the first signal conductor layer 18.

The third branch electrodes 38a and 38b are located on the first lower main surface S2. The third branch electrode 38a is electrically connected to the second branch conductor layer 72a. More specifically, the interlayer connection conductor v4 electrically connects the front end of the second branch conductor layer 72a and the third branch electrode 38a. The third branch electrode 38b is electrically connected to the second branch conductor layer 72b. More specifically, the interlayer connection conductor v5 (not illustrated) electrically connects a front end of the second branch conductor layer 72b and the third branch electrode 38b.

A second circuit board 110h of the circuit module 1h further includes fourth branch electrodes 138a and 138b (fourth branch electrode 138b is not illustrated). The fourth branch electrodes 138a and 138b are located on the second upper main surface S11. The fourth branch electrodes 138a and 138b are electrically connected to the second ground conductor layer 120a. The fourth branch electrode 138a is bonded to the third branch electrode 38a by using the conductive bonding material 200d. The fourth branch electrode 138b is bonded to the third branch electrode 38b by using a conductive bonding material 200e (not illustrated). The other structures of the circuit module 1h are the same as the structures of the circuit module 1b. The circuit module 1h can exhibit the effects (a) to (e) and (h).

### Ninth Modification Example

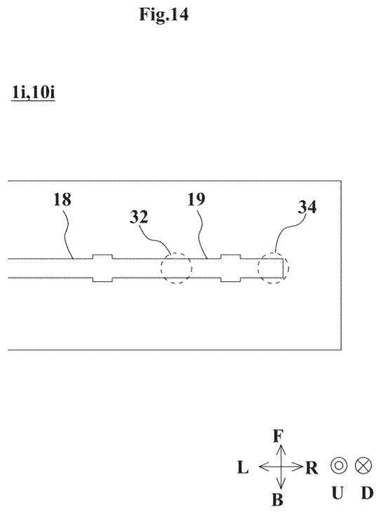

Hereinafter, a circuit module 1i according to a ninth modification example will be described with reference to the accompanying drawings. FIG. 14 is a top view of the first signal conductor layer 18, the first branch conductor layer 19, the first signal electrode 32, and the first branch electrode 34 of the circuit module 1i.

In the circuit module 1i, a line width of a part of the first signal conductor layer 18 is different from a line width of the remaining part of the first signal conductor layer 18 when viewed in the up-down direction. As a result, the characteristic impedance generated at a part of the first signal conductor layer 18 is different from the characteristic impedance generated at the remaining part of the first signal conductor layer 18. In the present exemplary embodiment, the line width of a part of the first signal conductor layer 18 is larger than the line width of the remaining part of the first signal conductor layer 18 when viewed in the up-down direction. As a result, the characteristic impedance generated at a part of the first signal conductor layer 18 is lower than the characteristic impedance generated at the remaining part of the first signal conductor layer 18.

In the circuit module 1i, a line width of a part of the first branch conductor layer 19 is different from a line width of the remaining part of the first branch conductor layer 19 when viewed in the up-down direction. As a result, the characteristic impedance generated at a part of the first branch conductor layer 19 is different from the characteristic impedance generated at the remaining part of the first branch conductor layer 19. In the present exemplary embodiment, the line width of a part of the first branch conductor layer 19 is larger than the line width of the remaining part of the first branch conductor layer 19 when viewed in the up-down direction. As a result, the characteristic impedance generated at a part of the first branch conductor layer 19 is lower than the characteristic impedance generated at the remaining part of the first branch conductor layer 19. The other structures of the circuit module 1i are the same as the structures of the circuit module 1, and thus the description thereof will be omitted. The circuit module 1i can exhibit the effects (a) to (e).

(i) With the circuit module 1i, the characteristic impedance generated at the connection portion between the first circuit board 10 and the second circuit board 110 is matched with the characteristic impedance generated at the first signal conductor layer 18 and the characteristic impedance generated at the second signal conductor layer 118 by adjusting the characteristic impedance generated at a part of the first signal conductor layer 18 and the characteristic impedance generated at a part of the first branch conductor layer 19.

### Tenth Modification Example

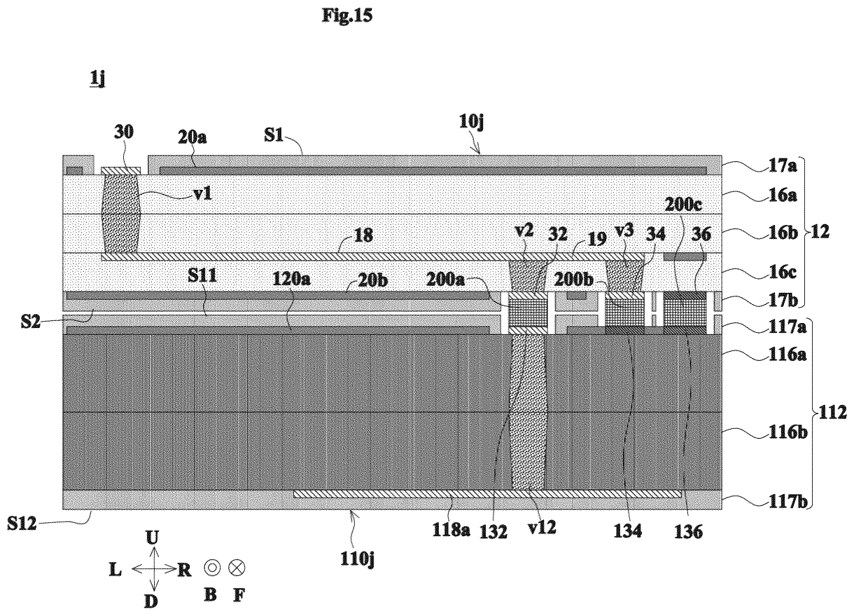

Hereinafter, a circuit module 1j according to a tenth modification example will be described with reference to the accompanying drawings. FIG. 15 is a cross-sectional view of the circuit module 1j.

A second circuit board 110j of the circuit module 1j includes a second radiation conductor layer 118a instead of the second signal conductor layer 118. Specifically, the second radiation conductor layer 118a is located on a lower main surface of the second dielectric layer 116b. The second radiation conductor layer 118a has a rectangular shape when viewed in the up-down direction. In addition, the second circuit board 110j includes the second ground conductor layer 120a that overlaps the second radiation conductor layer 118a when viewed in the up-down direction. As a result, the second radiation conductor layer 118a functions as a patch antenna. That is, the second radiation conductor layer 118a transmits or receives the electromagnetic waves.

In addition, the thickness of the first board body 12 in the up-down direction is smaller than a thickness of the second board body 112 in the up-down direction. Dielectric constants of the second dielectric layers 116a and 116b are higher than dielectric constants of the first dielectric layers 16a to 16c. The other structures of the circuit module 1j are the same as the structures of the circuit module 1, and thus the description thereof will be omitted. The circuit module 1j can exhibit the effects (a) to (e).

(j) With the circuit module 1j, the characteristic impedance generated at the first signal conductor layer 18 and the characteristic impedance generated at the second radiation conductor layer 118a are matched with each other, so that the power supplied from the first signal conductor layer 18 to the second radiation conductor layer 118a can be increased.

(k) With the circuit module 1j, it is possible to suppress the enlargement of the circuit module 1j in the up-down direction while improving the antenna characteristics. More specifically, as the thickness of the second board body 112 in the up-down direction is increased, the antenna characteristics are improved. Therefore, the thickness of the second board body 112 in the up-down direction is large. However, the circuit module 1j is enlarged. Therefore, in the circuit module 1j, the thickness of the first board body 12 in the up-down direction is smaller than the thickness of the second board body 112 in the up-down direction. As a result, the increase in the thickness of the second board body 112 in the up-down direction is canceled by the decrease in the thickness of the second board body 112 in the up-down direction. As a result, the enlargement of the circuit module 1j in the up-down direction can be suppressed.

(l) In the circuit module 1j, the dielectric constants of the second dielectric layers 116a to 116c are higher than the dielectric constants of the first dielectric layers 16a to 16c. As a result, the dielectric constant between the second ground conductor layer 120a and the second radiation conductor layer 118a is increased. Therefore, the thickness of the second board body 112 in the up-down direction can be reduced while maintaining the antenna characteristics.

### Eleventh Modification Example

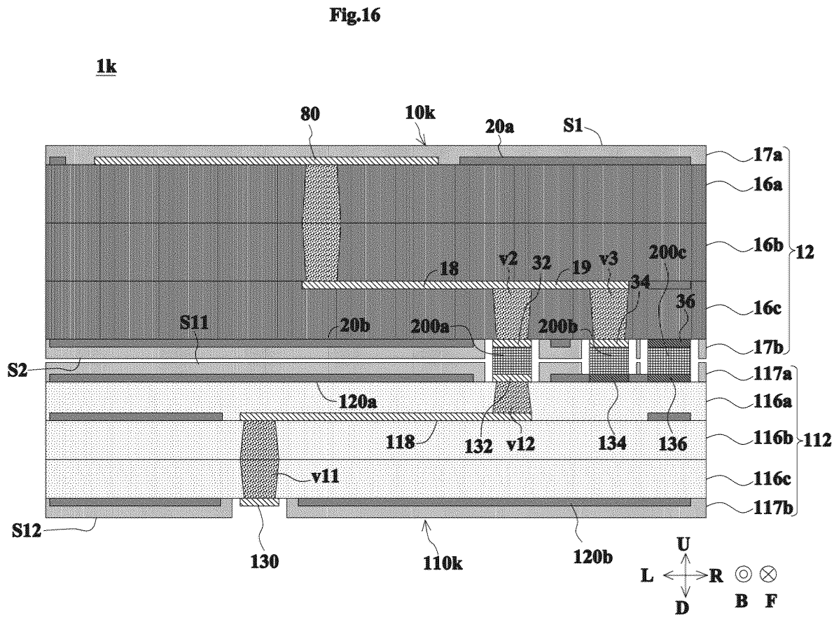

Hereinafter, a circuit module 1k according to an eleventh modification example will be described with reference to the accompanying drawings. FIG. 16 is a cross-sectional view of the circuit module 1k.

The circuit module 1k further includes a first radiation conductor layer 80 electrically connected to the first signal conductor layer 18. Specifically, the first radiation conductor layer 80 is a conductor layer provided in the first board body 12. The first radiation conductor layer 80 is located on the upper main surface of the first dielectric layer 16a. The first radiation conductor layer 80 has a rectangular shape when viewed in the up-down direction. The first radiation conductor layer 80 overlaps the first ground conductor layer 20b when viewed in the up-down direction. As a result, the first radiation conductor layer 80 functions as a patch antenna.

In addition, the thickness of the second board body 112 in the up-down direction is smaller than the thickness of the first board body 12 in the up-down direction. The dielectric constants of the first dielectric layers 16a to 16c are higher than the dielectric constants of the second dielectric layers 116a to 116c. The other structures of the circuit module 1k are the same as the structures of the circuit module 1, and thus the description thereof will be omitted. The circuit module 1k can exhibit the effects (a) to (e).

(m) With the circuit module 1k, the characteristic impedance generated at the first signal conductor layer 18 and the characteristic impedance generated at the second signal conductor layer 118, which is the antenna, are matched with each other, so that the power supplied from the second signal conductor layer 118 to the antenna can be increased.

(n) With the circuit module 1k, it is possible to suppress the enlargement of the circuit module 1k in the up-down direction while improving the antenna characteristics. More specifically, as the thickness of the first board body 12 in the up-down direction is increased, the antenna characteristics are improved. Therefore, the thickness of the first board body 12 in the up-down direction is large. However, the circuit module 1k is enlarged. Therefore, in the circuit module 1k, the thickness of the second board body 112 in the up-down direction is smaller than the thickness of the first board body 12 in the up-down direction. As a result, the increase in the thickness of the first board body 12 in the up-down direction is canceled by the decrease in the thickness of the second board body 112 in the up-down direction. As a result, the enlargement of the circuit module 1k in the up-down direction can be suppressed.

(o) In the circuit module 1k, the dielectric constants of the first dielectric layers 16a to 16c are higher than the dielectric constants of the second dielectric layers 116a to 116c. As a result, the dielectric constant between the first ground conductor layer 20b and the first radiation conductor layer 80 is increased. Therefore, the thickness of the first board body 12 in the up-down direction can be reduced while maintaining the antenna characteristics.

### Twelfth Modification Example

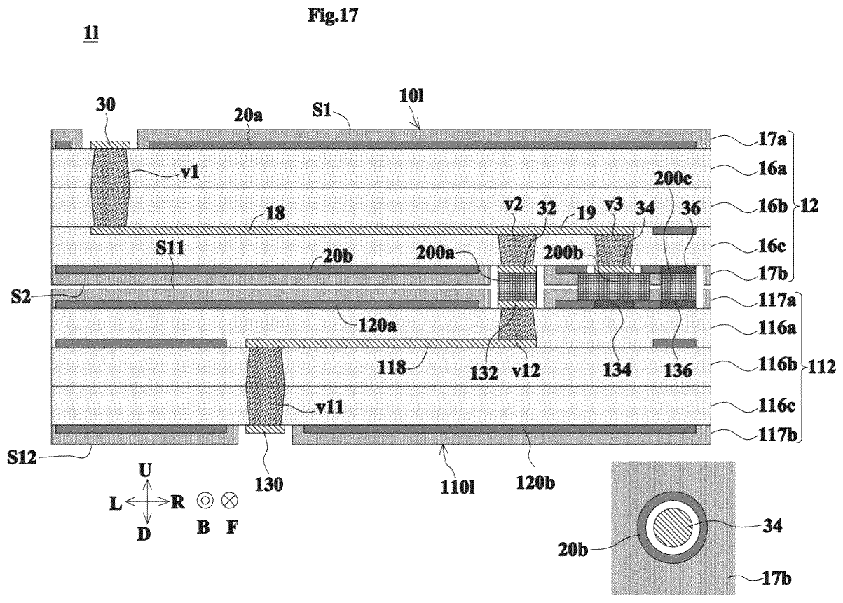

Hereinafter, a circuit module 1l according to a twelfth modification example will be described with reference to the accompanying drawings. FIG. 17 is a cross-sectional view of the circuit module 1l.

In a first circuit board 10l of the circuit module 1l, the first ground conductor layer 20b is provided at the same position as the first branch electrode 34 in the up-down direction. The first ground conductor layer 20b surrounds the first branch electrode 34 when viewed in the up-down direction. A part of the first ground conductor layer 20b is exposed to the outside of the first board body 12 along with the first branch electrode 34 through the opening provided in the first protective layer 17b. A part of the first ground conductor layer 20b is bonded to the second branch electrode 134 along with the first branch electrode 34 by using the conductive bonding material 200b. In addition, the first ground electrode 36 is a portion in which a ground conductor is exposed from the first protective layer 17b. The first ground electrode 36 is electrically connected to the second ground electrode 136 with the conductive bonding material 200c interposed therebetween. The other structures of the circuit module 1l are the same as the structures of the circuit module 1, and thus the description thereof will be omitted. The circuit module 1l can exhibit the effects (a) to (e).

(p) With the circuit module 1l, the first branch electrode 34 is electrically connected to the first ground conductor layer 20b by using the conductive bonding material 200b. As a result, the first ground conductor layer 20b is more reliably connected to the ground potential. In a case where the distance between the first board body 12 and the second board body 112 varies, even in a case where the thickness of the conductive bonding material 200b in the up-down direction varies, the first ground conductor layer 20b is more reliably connected to the ground potential.

### Thirteenth Modification Example

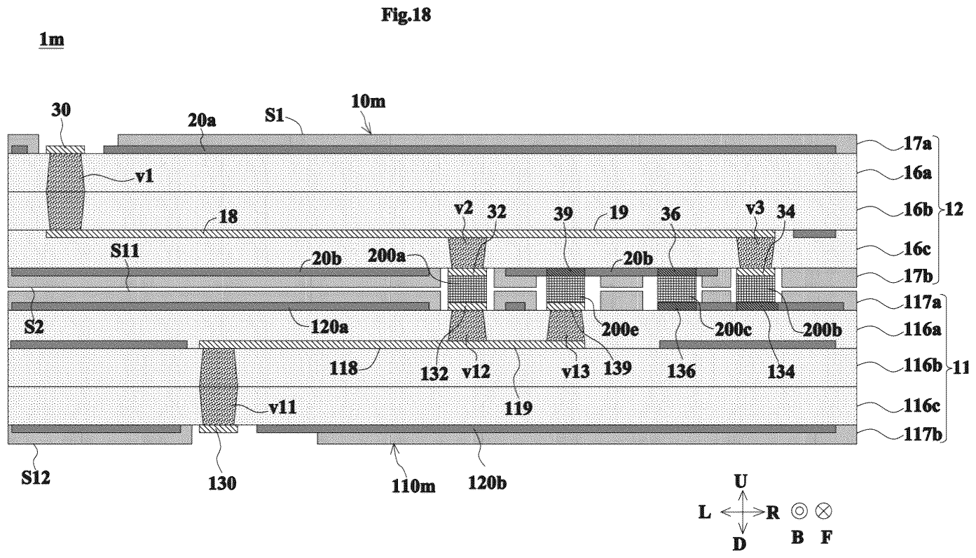

Hereinafter, a circuit module 1m according to a thirteenth modification example will be described with reference to the accompanying drawings. FIG. 18 is a cross-sectional view of the circuit module 1m.

A first circuit board 10m of the circuit module 1m further includes a fifth branch electrode 39. The fifth branch electrode 39 is located on the first lower main surface S2, and is electrically connected to the first ground conductor layer 20b.

The second circuit board 110m further includes a third branch conductor layer 119 and a sixth branch electrode 139. The third branch conductor layer 119 is provided in the second board body 112, and is electrically connected to the second signal conductor layer 118. The sixth branch electrode 139 is located on the second upper main surface S11, and is electrically connected to the third branch conductor layer 119. The sixth branch electrode 139 is bonded to the fifth branch electrode 39 by using the conductive bonding material 200e. The other structures of the circuit module 1m are the same as the structures of the circuit module 1, and thus the description thereof will be omitted. The circuit module 1m can exhibit the effects (a) to (e).

(q) In the circuit module 1m, the short stub is also provided in the second circuit board 110m. As a result, for the same reason as in (a), it is possible to suppress the deviation of the characteristic impedance generated at the connection portion between the first circuit board 10 and the second circuit board 110 from the desired characteristic impedance.

### Fourteenth Modification Example

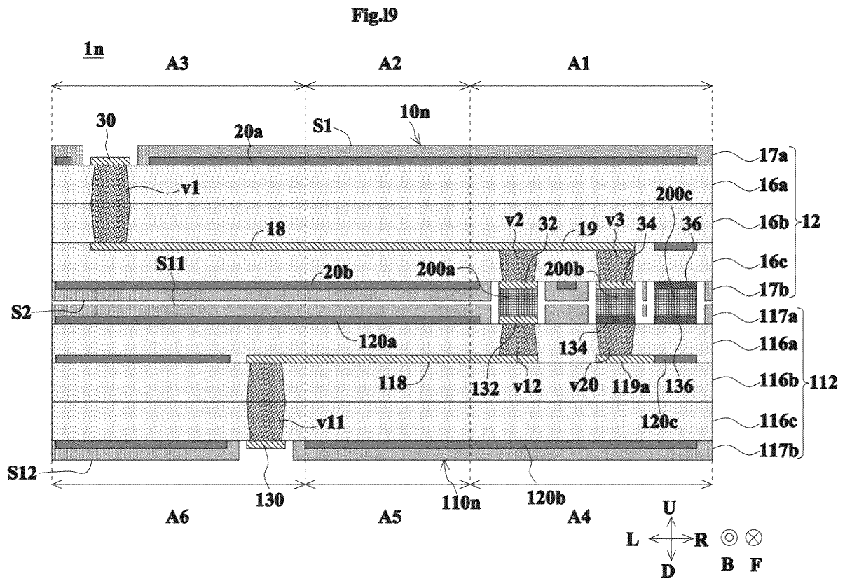

Hereinafter, a circuit module In according to a fourteenth modification example will be described with reference to the accompanying drawings. FIG. 19 is a cross-sectional view of the circuit module 1n.

A second circuit board 110n of the circuit module 1n further includes an interlayer connection conductor v20, a fourth branch conductor layer 119a, and a ground conductor layer 120c. The ground conductor layer 120c (second ground conductor layer) is located on the upper main surface of the second dielectric layer 116b. The fourth branch conductor layer 119a is located on the upper main surface of the second dielectric layer 116b. The fourth branch conductor layer 119a has a linear shape extending in the left-right direction when viewed in the up-down direction. A right end of the fourth branch conductor layer 119a is in contact with the ground conductor layer 120c. The interlayer connection conductor v20 penetrates the second dielectric layer 116a in the up-down direction. The interlayer connection conductor v20 electrically connects the fourth branch conductor layer 119a and the second branch electrode 134. The other structures of the circuit module In are the same as the structures of the circuit module 1, and thus the description thereof will be omitted. The circuit module In can exhibit the effects (a) to (e).

In the circuit module In as described above, the interlayer connection conductor v3, the first branch electrode 34, the second branch electrode 134, the conductive bonding material 200b, and the fourth branch conductor layer 119a function as a short stub.

### Fifteenth Modification Example

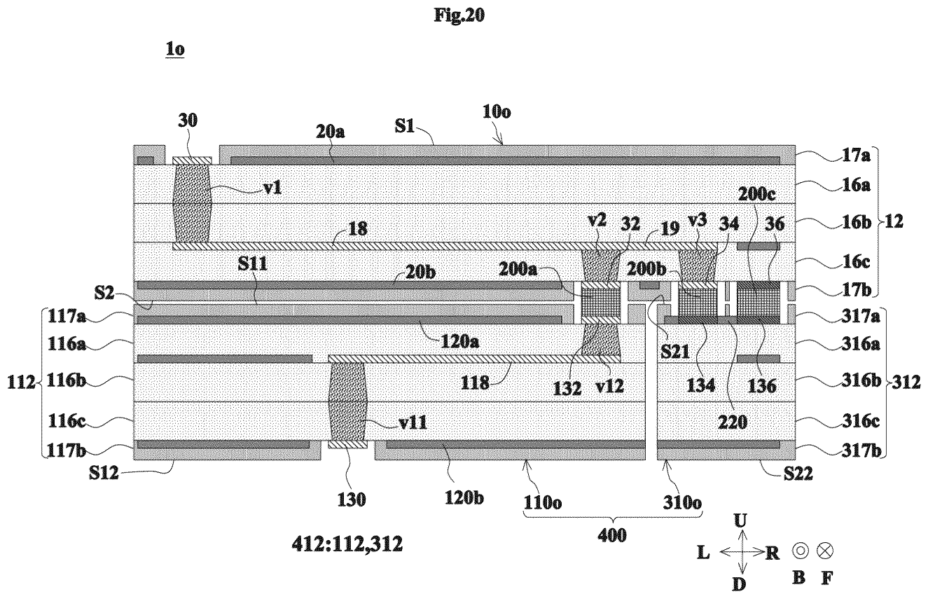

Hereinafter, a circuit module 1o according to a fifteenth modification example will be described with reference to the accompanying drawings. FIG. 20 is a cross-sectional view of the circuit module 1o.

The circuit module 1o is different from the circuit module 1 in that the circuit module 1o includes one or more circuit boards 400 including a second circuit board 110o and a third circuit board 310o. The one or more circuit boards 400 include one or more board bodies 412. The one or more board bodies 412 include the second board body 112 and a third board body 312.

The second circuit board 1100 includes the second board body 112. The second signal conductor layer 118 is provided in the second board body 112. The second board body 112 is any one of the one or more board bodies 412. The second signal electrode 132 is located on the second upper main surface S11 of the second board body 112. The second board body 112 is a board body provided with the second signal conductor layer 118 among the one or more board bodies 412. The second signal electrode 132 is electrically connected to the second signal conductor layer 118.

The third circuit board 310o includes the third board body 312 having a third upper main surface S21 and a third lower main surface S22. A second ground conductor layer 220 is provided in the third board body 312. The third board body 312 is any one of the one or more board bodies 412. The second branch electrode 134 is located on the third upper main surface S21 of the third board body 312. The third board body 312 is a board body provided with the second ground conductor layer 220 among the one or more board bodies 412. The second branch electrode 134 is electrically connected to the second ground conductor layer 220.

As described above, the circuit module 1o has a structure in which the second circuit board 110 of the circuit module 1 is separated into the second circuit board 1100 and the third circuit board 310o. The other structures of the circuit module 1o are the same as the structures of the circuit module 1, and thus the description thereof will be omitted. The circuit module 1o can exhibit the effects (a) to (e).

### Sixteenth Modification Example

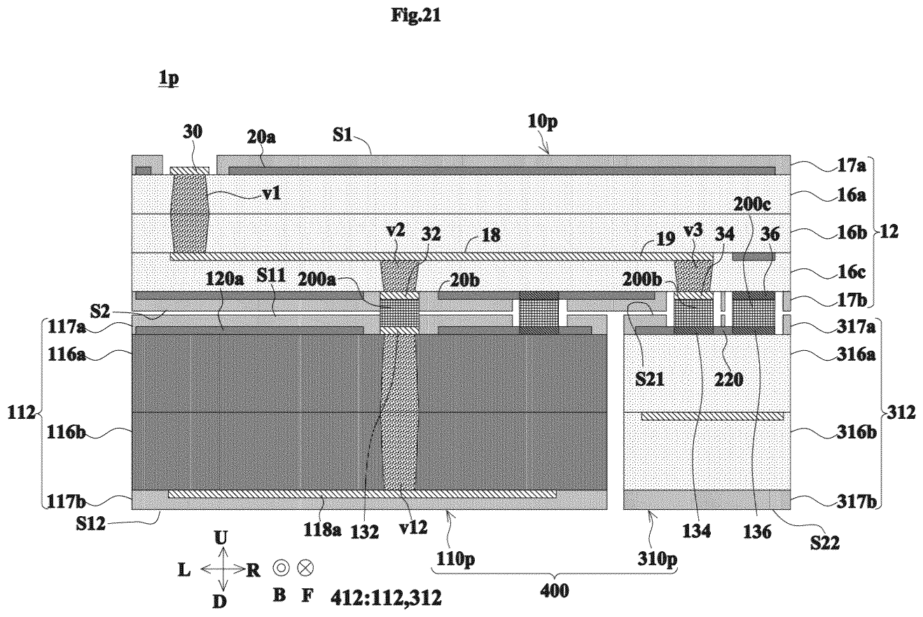

Hereinafter, a circuit module 1p according to a sixteenth modification example will be described with reference to the accompanying drawings. FIG. 21 is a cross-sectional view of the circuit module 1p.

The circuit module 1p is different from the circuit module 1j in that the circuit module 1p includes one or more circuit boards 400 including a second circuit board 110p and a third circuit board 310p. The one or more circuit boards 400 include one or more board bodies 412. The one or more board bodies 412 include the second board body 112 and the third board body 312.

The second circuit board 110p includes the second board body 112. The second radiation conductor layer 118a is provided in the second board body 112. The second board body 112 is any one of the one or more board bodies 412. The second signal electrode 132 is located on the second upper main surface S11 of the second board body 112. The second board body 112 is a board body provided with the second radiation conductor layer 118a among the one or more board bodies 412. The second signal electrode 132 is electrically connected to the second radiation conductor layer 118a.

The third circuit board 310p includes the third board body 312 having the third upper main surface S21 and the third lower main surface S22. The second ground conductor layer 220 is provided in the third board body 312. The third board body 312 is any one of the one or more board bodies 412. The second branch electrode 134 is located on the third upper main surface S21 of the third board body 312. The third board body 312 is a board body provided with the second ground conductor layer 220 among the one or more board bodies 412. The second branch electrode 134 is electrically connected to the second ground conductor layer 220.

As described above, the circuit module 1p has a structure in which the second circuit board 110j of the circuit module 1j is separated into the second circuit board 110p and the third circuit board 310p. The other structures of the circuit module 1p are the same as the structures of the circuit module 1j, and thus the description thereof will be omitted. The circuit module 1p can exhibit the effects (a) to (e), (j), (k), and (l).

### Seventeenth Modification Example

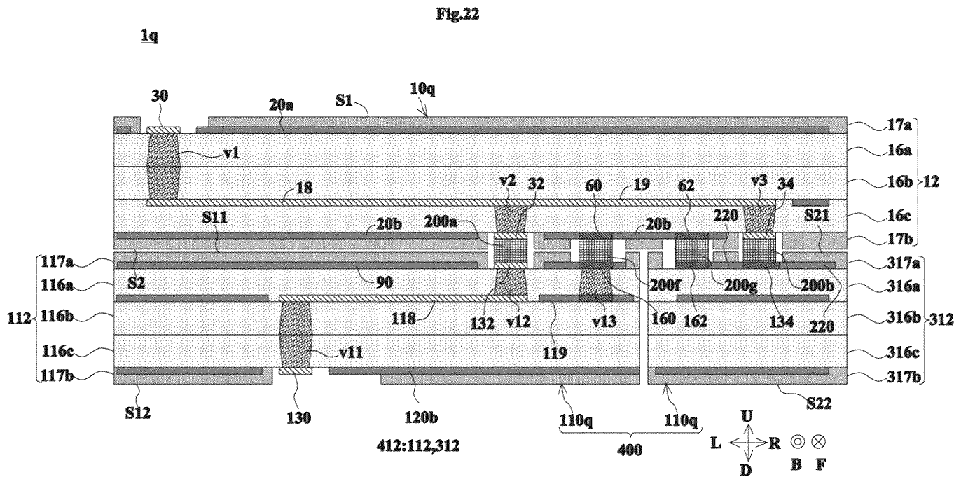

Hereinafter, a circuit module 1q according to a seventeenth modification example will be described with reference to the accompanying drawings. FIG. 22 is a cross-sectional view of the circuit module 1q.

The circuit module 1q is different from the circuit module 1o in that the circuit module 1q further includes a first ground electrode 60, a sixth ground electrode 62, a fourth ground conductor layer 90, a seventh ground electrode 162, and the second ground conductor layer 220. The fourth ground conductor layer 90 is provided in the second board body 112. The fifth ground electrode 160 is located on the second upper main surface S11, and is electrically connected to the fourth ground conductor layer 90. The fifth ground electrode 160 is located between the second signal electrode 132 and the second branch electrode 134 when viewed in the up-down direction.

The second ground conductor layer 220 is provided in the third board body 312. The seventh ground electrode 162 is located on the third upper main surface S21, and is electrically connected to the second ground conductor layer 220. The seventh ground electrode 162 is located between the second signal electrode 132 and the second branch electrode 134 when viewed in the up-down direction.

The first ground electrode 60 is bonded to the fifth ground electrode 160 by using a conductive bonding material 200f. The sixth ground electrode 62 is bonded to the seventh ground electrode 162 by using a conductive bonding material 200g. The other structures of the circuit module 1q are the same as the structures of the circuit module 1o, and thus the description thereof will be omitted. The circuit module 1q can exhibit the effects (a) to (e).

In the circuit module 1q, the fifth ground electrode 160 is located between the second signal electrode 132 and the second branch electrode 134 when viewed in the up-down direction. The seventh ground electrode 162 is located between the second signal electrode 132 and the second branch electrode 134 when viewed in the up-down direction. As a result, a leakage of an electromagnetic field between the second signal electrode 132 and the second branch electrode 134 is suppressed.

### Eighteenth Modification Example

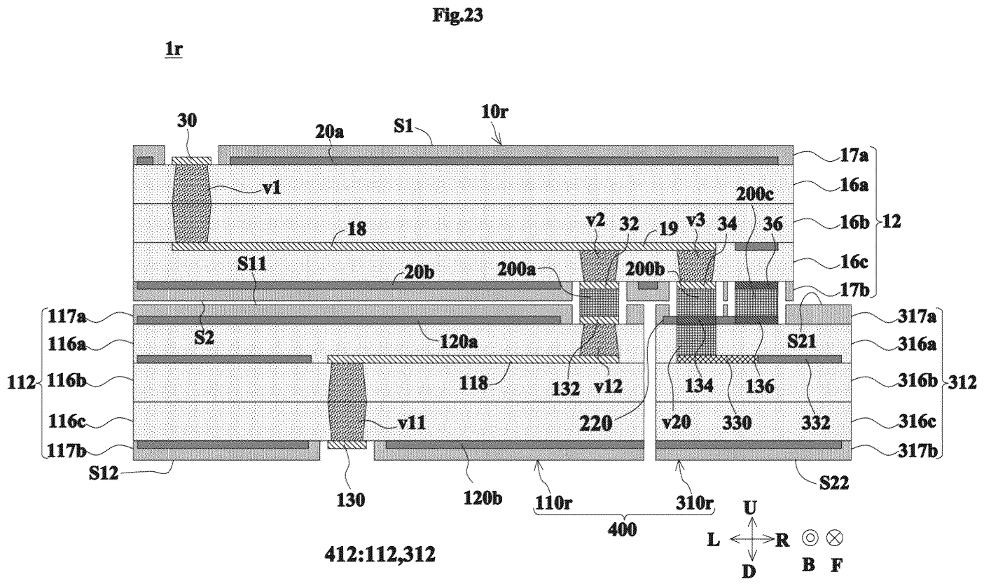

Hereinafter, a circuit module 1r according to an eighteenth modification example will be described with reference to the accompanying drawings. FIG. 23 is a cross-sectional view of the circuit module 1r.

The circuit module 1r is different from the circuit module 1o in that a third circuit board 310r further includes a wiring conductor layer 330, a fifth ground conductor layer 332, and the interlayer connection conductor v20. The wiring conductor layer 330 and the fifth ground conductor layer 332 are provided in the third board body 312. The wiring conductor layer 330 is in contact with the fifth ground conductor layer 332. However, a line width of the wiring conductor layer 330 is narrower than a line width of the fifth ground conductor layer 332.

The interlayer connection conductor v20 electrically connects the second branch electrode 134 and the wiring conductor layer 330. As a result, the second branch electrode 134 is electrically connected to the fifth ground conductor layer 332 with the wiring conductor layer 330 interposed therebetween. The other structures of the circuit module 1r are the same as the structures of the circuit module 1o, and thus the description thereof will be omitted. The circuit module 1r can exhibit the effects (a) to (e).

### Nineteenth Modification Example

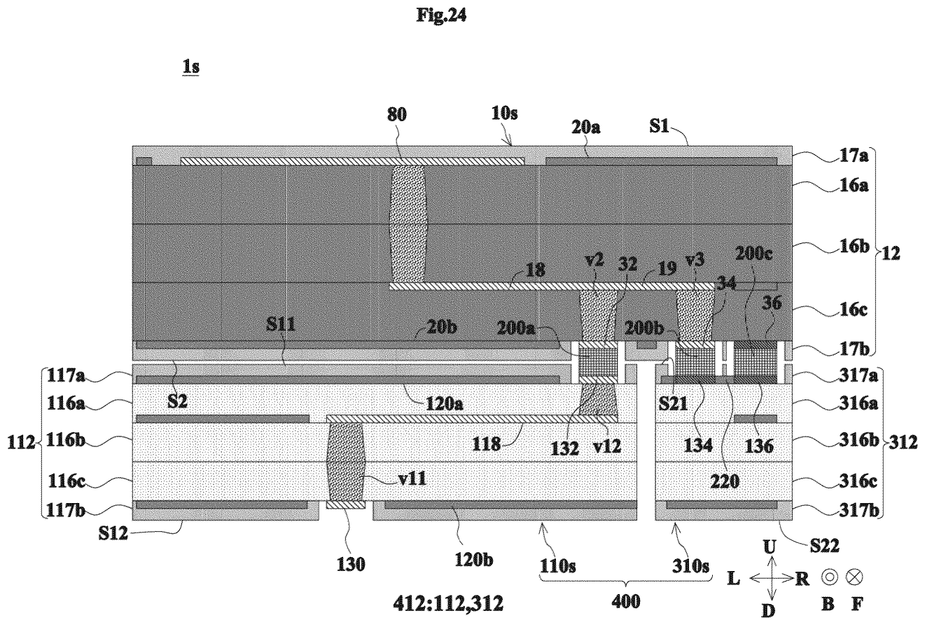

Hereinafter, a circuit module 1s according to a nineteenth modification example will be described with reference to the accompanying drawings. FIG. 24 is a cross-sectional view of the circuit module 1s.

The circuit module 1s is different from the circuit module 1k in that the circuit module 1s includes one or more circuit boards 400 including a second circuit board 110s and a third circuit board 310s. The one or more circuit boards 400 include one or more board bodies 412. The one or more board bodies 412 include the second board body 112 and the third board body 312.

The second circuit board 110s includes the second board body 112. The second signal conductor layer 118 is provided in the second board body 112. The second signal electrode 132 is located on the second upper main surface S11. The second signal electrode 132 is electrically connected to the second signal conductor layer 118.

The third circuit board 310s includes the third board body 312 having the third upper main surface S21 and the third lower main surface S22. The second ground conductor layer 220 is provided in the third board body 312. The second branch electrode 134 is located on the third upper main surface S21. The second branch electrode 134 is electrically connected to the second ground conductor layer 220.

As described above, the circuit module 1s has a structure in which a second circuit board 110k of the circuit module 1k is separated into the second circuit board 110s and the third circuit board 310s. The other structures of the circuit module 1s are the same as the structures of the circuit module 1k, and thus the description thereof will be omitted. The circuit module 1s can exhibit the effects (a) to (e), (m), (n), and (o).

### Twentieth Modification Example

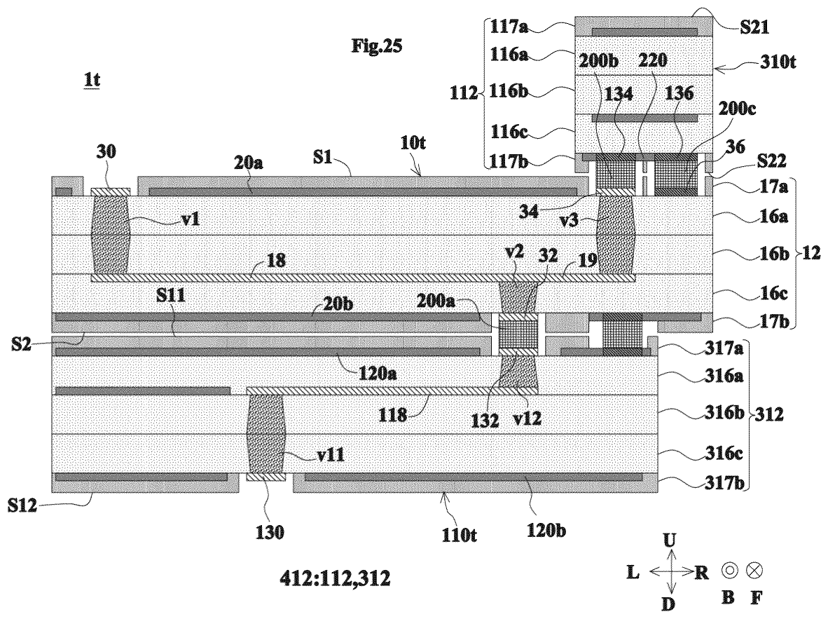

Hereinafter, a circuit module 1t according to a twentieth modification example will be described with reference to the accompanying drawings. FIG. 25 is a cross-sectional view of the circuit module 1t.

The circuit module It is different from the circuit module 1o in a position of a third circuit board 310t. More specifically, the third circuit board 310t is located above the first circuit board 10t. Therefore, the first branch electrode 34 is located on the first upper main surface S1. The second branch electrode 134 is located on the third lower main surface S22. The first branch electrode 34 is bonded to the second branch electrode 134 by using the conductive bonding material 200b. The other structures of the circuit module 1t are the same as the structures of the circuit module 1o, and thus the description thereof will be omitted. The circuit module 1s can exhibit the effects (a) to (e).

### OTHER EMBODIMENTS

The circuit module according to the present disclosure is not limited to the circuit modules 1 and 1a to 1s, and can be changed within the scope of the gist of the present disclosure. In addition, the structures of the circuit modules 1 and 1a to 1s may be combined in any manner.

The first circuit board according to the present disclosure is not limited to the first circuit boards 10 and 10a to 10s, and can be changed within the scope of the gist of the present disclosure. In addition, the structures of the first circuit board 10 and the first circuit boards 10a to 10s may be combined in any manner.

The third ground conductor layer 20a, the first ground conductor layer 20b, the first ground electrode 36, the ground conductor layer 120b, the second ground electrode 136, the protective layer 17a, the first protective layer 17b, the second protective layer 117a, and the protective layer 117b are not essential configuration requirements.

The first circuit board 10h may include three or more second branch conductor layers and three or more third branch electrodes. The second circuit board 110h may include three or more fourth branch electrodes.

In a first circuit board 10i, the line width of a part of the first signal conductor layer 18 may be smaller than the line width of the remaining part of the first signal conductor layer 18 when viewed in the up-down direction. In the first circuit board 10i, the line width of a part of the first branch conductor layer 19 may be smaller than the line width of the remaining part of the first branch conductor layer 19 when viewed in the up-down direction.

In the circuit module 1j, the thickness of the first board body 12 in the up-down direction may be equal to or larger than the thickness of the second board body 112 in the up-down direction.

The second circuit board 110j in the circuit module 1j may have the structure described below. The second dielectric layers 116a and 116b include one or more third dielectric layers. A dielectric constant of the third dielectric layer is higher than the dielectric constants of the first dielectric layers 16a to 16c and the dielectric constants of the dielectric layers excluding the third dielectric layer among the second dielectric layers 116a and 116b. The one or more third dielectric layers is, for example, the second dielectric layer 116b. In this case, the dielectric constant of the second dielectric layer 116b, which is the third dielectric layer, is higher than the dielectric constants of the first dielectric layers 16a to 16c, and the dielectric constant of the second dielectric layer 116a.

In the circuit module 1k, the thickness of the second board body 112 in the up-down direction may be equal to or larger than the thickness of the first board body 12 in the up-down direction.

The second circuit board 110k in the circuit module 1k may have the structure described below. The plurality of first dielectric layers 16a to 16c include one or more fourth dielectric layers. A dielectric constant of the fourth dielectric layer is higher than the dielectric constants of the dielectric layers excluding the fourth dielectric layer among the first dielectric layers 16a to 16c and the dielectric constant of the second dielectric layers 116a to 116c. The one or more fourth dielectric layers are, for example, the first dielectric layer 16c. In this case, the dielectric constant of the first dielectric layer 16c, which is the fourth dielectric layer, is higher than the dielectric constants of the first dielectric layers 16a and 16b, and the dielectric constants of the second dielectric layers 116a to 116c.

The first circuit board and the second circuit board are referred to as the circuit boards for convenience, but are concepts including electronic components.

The second radiation conductor layer 118a and the first radiation conductor layer 80 may be antennas other than the patch antenna. Examples of the antennas other than the patch antenna include a dipole antenna and a monopole antenna.

The first circuit board and the second circuit board need not have flexibility.

Any one of the third ground conductor layer 20a or the first ground conductor layer 20b need not be provided. In this case, the first signal conductor layer 18 and the third ground conductor layer 20a have a microstrip line structure. The first signal conductor layer 18 and the first ground conductor layer 20b have a microstrip line structure.

Both the first board body 12 and the second board body 112 may be bent.

In the circuit module 1p, the third circuit board 310p may be located above the first circuit board 10p. In this case, the first branch electrode 34 is located on the first upper main surface S1. The second branch electrode 134 is located on the third lower main surface S22. The first branch electrode 34 is bonded to the second branch electrode 134 by using the conductive bonding material 200b.

The present disclosure has the structure described below.

(1)

A circuit module including: a first circuit board; and one or more circuit boards, in which the one or more circuit boards have a portion overlapping the first circuit board when viewed in an up-down direction, the first circuit board includes a first board body having a first upper main surface and a first lower main surface, a first signal conductor layer provided in the first board body, a first branch conductor layer provided in the first board body and electrically connected to the first signal conductor layer, a first signal electrode located on the first lower main surface, and a first branch electrode located on the first upper main surface or the first lower main surface, the one or more circuit boards include one or more board bodies having an upper main surface and a lower main surface, a second signal conductor layer provided in any one of the one or more board bodies, a second ground conductor layer provided in any one of the one or more board bodies, a second signal electrode located on the upper main surface of the board body provided with the second signal conductor layer among the one or more board bodies, and a second branch electrode located on the upper main surface or the lower main surface of the board body provided with the second ground conductor layer among the one or more board bodies, the first signal electrode is electrically connected to the first signal conductor layer, the first branch electrode is electrically connected to the first branch conductor layer, the second signal electrode is electrically connected to the second signal conductor layer and is bonded to the first signal electrode by using a conductive bonding material, and the second branch electrode is electrically connected to the second ground conductor layer and is bonded to the first branch electrode by using a conductive bonding material.

(2)

The circuit module according to (1), in which the first circuit board further includes a first ground conductor layer provided in the first board body.

(3)

The circuit module according to (2), in which the first ground conductor layer overlaps the first signal conductor layer when viewed in the up-down direction.

(4)

The circuit module according to (2) or (3), in which the one or more circuit boards include a second circuit board, the second circuit board includes a second board body having a second upper main surface and a second lower main surface, the first branch electrode is located on the first lower main surface, the second branch electrode is located on the second upper main surface, the first circuit board further includes one or more first ground electrodes located on the first lower main surface and electrically connected to the first ground conductor layer, the second circuit board further includes one or more second ground electrodes located on the second upper main surface and electrically connected to the second ground conductor layer, and the one or more second ground electrodes are bonded to the one or more first ground electrodes by using one or more conductive bonding materials.

(5)

The circuit module according to (4), in which the one or more first ground electrodes include a third ground electrode, and when viewed in the up-down direction, a distance between the first signal electrode and the first branch electrode is longer than a distance between the first signal electrode and the third ground electrode, and a distance between the first branch electrode and the third ground electrode.

(6)

The circuit module according to (5), in which the one or more first ground electrodes further include a fourth ground electrode, and when viewed in the up-down direction, the distance between the first signal electrode and the first branch electrode is shorter than a distance between the first signal electrode and the fourth ground electrode, and a distance between the first branch electrode and the fourth ground electrode.

(7)

The circuit module according to any one of (1) to (6), in which the first circuit board further includes an open stub conductor layer electrically connected to the first signal conductor layer or the first branch conductor layer, and the open stub conductor layer is not electrically connected to an electrode other than an electrode to which the first signal conductor layer is electrically connected.

(8)

The circuit module according to any one of (1) to (7), in which the one or more circuit boards include a second circuit board, the second circuit board includes a second board body having a second upper main surface and a second lower main surface, the first branch electrode is located on the first lower main surface, the second branch electrode is located on the second upper main surface, the first circuit board further includes one or more second branch conductor layers provided in the first board body and electrically connected to the first signal conductor layer, and one or more third branch electrodes located on the first lower main surface, the second circuit board further includes one or more fourth branch electrodes located on the second upper main surface, the one or more third branch electrodes are electrically connected to the one or more second branch conductor layers, and the one or more fourth branch electrodes are electrically connected to the second ground conductor layer and are bonded to the one or more third branch electrodes by using a conductive bonding material.

(9)

The circuit module according to any one of (1) to (8), in which a line width of a part of the first signal conductor layer is different from a line width of a remaining part of the first signal conductor layer when viewed in the up-down direction.

(10)

The circuit module according to any one of (1) to (9), in which a line width of a part of the first branch conductor layer is different from a line width of a remaining part of the first branch conductor layer when viewed in the up-down direction.

(11)

The circuit module according to (10), in which the one or more circuit boards include a second circuit board, the second circuit board includes a second board body having a second upper main surface and a second lower main surface, the first branch electrode is located on the first lower main surface, the second branch electrode is located on the second upper main surface, and a thickness of the first board body in the up-down direction is smaller than a thickness of the second board body in the up-down direction.

(12)

The circuit module according to any one of (10) or (11), in which the first board body has a structure in which a plurality of first dielectric layers are laminated in the up-down direction, the second board body has a structure in which a plurality of second dielectric layers are laminated in the up-down direction, the plurality of second dielectric layers include one or more third dielectric layers, and a dielectric constant of the third dielectric layer is higher than dielectric constants of the plurality of first dielectric layers and dielectric constants of dielectric layers excluding the third dielectric layer among the plurality of second dielectric layers.

(13)

The circuit module according to any one of (1) to (10), in which the first circuit board further includes an antenna provided in the first board body and electrically connected to the first signal conductor layer.

(14)

The circuit module according to (13), in which the one or more circuit boards include a second circuit board, the second circuit board includes a second board body having a second upper main surface and a second lower main surface, the first branch electrode is located on the first lower main surface, the second branch electrode is located on the second upper main surface, and a thickness of the second board body in the up-down direction is smaller than a thickness of the first board body in the up-down direction.

(15)

The circuit module according to any one of (13) or (14), in which the one or more circuit boards include a second circuit board, the second circuit board includes a second board body having a second upper main surface and a second lower main surface, the first branch electrode is located on the first lower main surface, the second branch electrode is located on the second upper main surface, the first board body has a structure in which a plurality of first dielectric layers are laminated in the up-down direction, the second board body has a structure in which a plurality of second dielectric layers are laminated in the up-down direction, the plurality of first dielectric layers include one or more fourth dielectric layers, and a dielectric constant of the fourth dielectric layer is higher than dielectric constants of dielectric layers excluding the fourth dielectric layer among the plurality of first dielectric layers and dielectric constants of the plurality of second dielectric layers.

(16)

The circuit module according to any one of (13) to (15), in which the first circuit board further includes a third ground conductor layer provided in the first board body, and the third ground conductor layer overlaps the first signal conductor layer when viewed in the up-down direction and overlaps the first signal electrode and the first branch electrode when viewed in the up-down direction.

(17)

The circuit module according to any one of (1) to (16), in which the one or more circuit boards include a second circuit board, the second circuit board includes a second board body having a second upper main surface and a second lower main surface, the first branch electrode is located on the first lower main surface, the second branch electrode is located on the second upper main surface, the first board body includes a first protective layer laminated at a lowermost part in the first board body, the second board body includes a second protective layer laminated at an uppermost part in the first board body, the first signal electrode and the first branch electrode are exposed to an outside of the first board body through an opening provided in the first protective layer, and the second signal electrode and the second branch electrode are exposed to an outside of the second board body through an opening provided in the second protective layer.

(18)

The circuit module according to (17), in which the first circuit board further includes a first ground conductor layer provided in the first board body and provided at the same position as the first branch electrode in the up-down direction, the first ground conductor layer surrounds the first branch electrode when viewed in the up-down direction, a part of the first ground conductor layer is exposed to the outside of the first board body along with the first branch electrode through the opening provided in the first protective layer, and a part of the first ground conductor layer is bonded to the second branch electrode along with the first branch electrode by using a conductive bonding material.

(19)

The circuit module according to any one of (2) to (6), in which the one or more circuit boards include a second circuit board, the second circuit board includes a second board body having a second upper main surface and a second lower main surface, the first branch electrode is located on the first lower main surface, the second branch electrode is located on the second upper main surface, the first circuit board further includes a fifth branch electrode located on the first lower main surface and electrically connected to the first ground conductor layer, the second circuit board further includes a third branch conductor layer provided in the second board body and electrically connected to the second signal conductor layer, and a sixth branch electrode located on the second upper main surface and electrically connected to the third branch conductor layer, and the sixth branch electrode is bonded to the fifth branch electrode by using a conductive bonding material.

(20)

The circuit module according to any one of (1) to (19), in which the first board body has flexibility, the first board body has a first section and a second section, the up-down direction in the first section is defined as a Z-axis direction, and the second section is bent in the Z-axis direction with respect to the first section.

(21)

The circuit module according to any one of (1) to (20), in which the one or more circuit boards include a second circuit board, the second circuit board includes a second board body having a second upper main surface and a second lower main surface, the first branch electrode is located on the first lower main surface, the second branch electrode is located on the second upper main surface, the second board body has flexibility, the second board body has a fourth section and a fifth section, the up-down direction in the fourth section is defined as a Z-axis direction, and the fifth section is bent in the Z-axis direction with respect to the fourth section.

(22)

The circuit module according to (1), in which the one or more circuit boards include a second circuit board and a third circuit board, the second circuit board includes a second board body having a second upper main surface and a second lower main surface, the third circuit board includes a third board body having a third upper main surface and a third lower main surface, the second signal conductor layer is provided in the second board body, the second ground conductor layer is provided in the third board body, the second signal electrode is located on the second upper main surface, and the second branch electrode is located on the third upper main surface or the third lower main surface.

(23)

The circuit module according to (22), in which the first circuit board further includes a first ground conductor layer provided in the first board body, and a first ground electrode located on the first lower main surface and electrically connected to the first ground conductor layer, the second board body further includes a fourth ground conductor layer provided in the second board body, and a fifth ground electrode located on the second upper main surface and electrically connected to the fourth ground conductor layer, and the first ground electrode is bonded to the fifth ground electrode by using a conductive bonding material.

(24)

The circuit module according to (23), in which the fifth ground electrode is located between the second signal electrode and the second branch electrode when viewed in the up-down direction.

(25)

The circuit module according to any one of (22) to (24), in which the first circuit board further includes a first ground conductor layer provided in the first board body, and a sixth ground electrode located on the first lower main surface and electrically connected to the first ground conductor layer, the third circuit board further includes a seventh ground electrode located on the third upper main surface and electrically connected to the second ground conductor layer, and the sixth ground electrode is bonded to the seventh ground electrode by using a conductive bonding material.

(26)

The circuit module according to (25), in which the seventh ground electrode is located between the second signal electrode and the second branch electrode when viewed in the up-down direction.

(27)

The circuit module according to any one of (22) to (26), in which the first circuit board further includes a first radiation conductor layer that transmits or receives electromagnetic waves, that is provided in the first board body, and that is electrically connected to the first signal conductor layer.

(28)

The circuit module according to any one of (22) to (27), in which the third circuit board further includes a fifth ground conductor layer provided in the third board body, and a wiring conductor layer provided in the third board body, and the second branch electrode is electrically connected to the fifth ground conductor layer with the wiring conductor layer interposed between the second branch electrode and the fifth ground conductor layer.

(29)

The circuit module according to (22), in which the first branch electrode is located on the first upper main surface, and the second branch electrode is located on the third upper main surface.

(30)

A circuit module including: a first circuit board; and one or more circuit boards, in which the one or more circuit boards have a portion overlapping the first circuit board when viewed in an up-down direction, the first circuit board includes a first board body having a first upper main surface and a first lower main surface, a first signal conductor layer provided in the first board body, a first branch conductor layer provided in the first board body and electrically connected to the first signal conductor layer, a first signal electrode located on the first lower main surface, and a first branch electrode located on the first upper main surface or the first lower main surface, the one or more circuit boards include one or more board bodies having an upper main surface and a lower main surface, a second radiation conductor layer that transmits or receives electromagnetic waves and that is provided in any one of the one or more board bodies, a second ground conductor layer provided in any one of the one or more board bodies, a second signal electrode located on the upper main surface of the board body provided with the second radiation conductor layer among the one or more board bodies, and a second branch electrode located on the upper main surface or the lower main surface of the board body provided with the second ground conductor layer among the one or more board bodies, the first signal electrode is electrically connected to the first signal conductor layer, the first branch electrode is electrically connected to the first branch conductor layer, the second signal electrode is electrically connected to the second radiation conductor layer and is bonded to the first signal electrode by using a conductive bonding material, and the second branch electrode is electrically connected to the second ground conductor layer and is bonded to the first branch electrode by using a conductive bonding material.

(31)

The circuit module according to (30), in which the one or more circuit boards include a second circuit board and a third circuit board, the second circuit board includes a second board body having a second upper main surface and a second lower main surface, the third circuit board includes a third board body having a third upper main surface and a third lower main surface, the second radiation conductor layer is provided in the second board body, the second ground conductor layer is provided in the third board body, the second signal electrode is located on the second upper main surface, and the second branch electrode is located on the third upper main surface or the third lower main surface.

(32)

A first circuit board including: a first board body having a first upper main surface and a first lower main surface; a first signal conductor layer provided in the first board body; a first branch conductor layer provided in the first board body and electrically connected to the first signal conductor layer; a first signal electrode located on the first lower main surface; and a first branch electrode located on the first upper main surface or the first lower main surface, in which the first signal electrode is electrically connected to the first signal conductor layer, and the first branch electrode is electrically connected to the first branch conductor layer and, when the first circuit board is connected to one or more circuit boards, is connected to a ground potential by being bonded to a second branch electrode of the one or more circuit boards by using a conductive bonding material.

### REFERENCE SIGNS LIST

1, 1a to 1s circuit module
10, 10a to 10s first circuit board
12 first board body
16a to 16c first dielectric layer
17a protective layer
17b first protective layer
18 first signal conductor layer
19 first branch conductor layer
20a third ground conductor layer
20b first ground conductor layer
30 upper surface signal electrode
32 first signal electrode
34 first branch electrode
36 first ground electrode
36a third ground electrode
36b fourth ground electrode
38a, 38b third branch electrode
39 fifth branch electrode
50, 150 connector
70a, 70b open stub conductor layer
72a, 72b second branch conductor layer
110, 110g, 110h, 110j, 110k, 110m, 110n second circuit board
112 second board body
116a to 116c second dielectric layer
117a second protective layer
117b protective layer
118 second signal conductor layer
80 first radiation conductor layer
118a second radiation conductor layer
119 third branch conductor layer
120a second ground conductor layer
120b ground conductor layer
130 lower surface signal electrode
132 second signal electrode
134 second branch electrode
136 second ground electrode
138a, 138b fourth branch electrode
139 sixth branch electrode
200a to 200e conductive bonding material
A1 first section
A2 second section
A3 third section
A4 fourth section
A5 fifth section
A6 sixth section
S1 first upper main surface
S11 second upper main surface
S12 second lower main surface
S2 first lower main surface

1. A circuit module comprising:
a first circuit board; and
one or more circuit boards,
wherein the one or more circuit boards include a portion overlapping the first circuit board when viewed in an up-down direction,
the first circuit board includes
a first board body including a first upper main surface and a first lower main surface,
a first signal conductor layer provided in the first board body,
a first branch conductor layer provided in the first board body and electrically connected to the first signal conductor layer,
a first signal electrode located on the first lower main surface, and
a first branch electrode located on the first upper main surface or the first lower main surface,
the one or more circuit boards include
one or more board bodies including an upper main surface and a lower main surface,
a second signal conductor layer provided in any one of the one or more board bodies,
a second ground conductor layer provided in any one of the one or more board bodies,
a second signal electrode located on the upper main surface of the board body provided with the second signal conductor layer among the one or more board bodies, and
a second branch electrode located on the upper main surface or the lower main surface of the board body provided with the second ground conductor layer among the one or more board bodies,
the first signal electrode is electrically connected to the first signal conductor layer,
the first branch electrode is electrically connected to the first branch conductor layer,
the second signal electrode is electrically connected to the second signal conductor layer and is bonded to the first signal electrode by using a conductive bonding material, and
the second branch electrode is electrically connected to the second ground conductor layer and is bonded to the first branch electrode by using a conductive bonding material.

2. The circuit module according to claim 1,
wherein the first circuit board further includes a first ground conductor layer provided in the first board body.

3. The circuit module according to claim 2,
wherein the first ground conductor layer overlaps the first signal conductor layer when viewed in the up-down direction.

4. The circuit module according to claim 2,
wherein the one or more circuit boards include a second circuit board,
the second circuit board includes a second board body including a second upper main surface and a second lower main surface,
the first branch electrode is located on the first lower main surface,
the second branch electrode is located on the second upper main surface,
the first circuit board further includes one or more first ground electrodes located on the first lower main surface and electrically connected to the first ground conductor layer,
the second circuit board further includes one or more second ground electrodes located on the second upper main surface and electrically connected to the second ground conductor layer, and
the one or more second ground electrodes are bonded to the one or more first ground electrodes by using one or more conductive bonding materials.

5. The circuit module according to claim 4,
wherein the one or more first ground electrodes include a third ground electrode, and
when viewed in the up-down direction, a distance between the first signal electrode and the first branch electrode is longer than a distance between the first signal electrode and the third ground electrode, and a distance between the first branch electrode and the third ground electrode.

6. The circuit module according to claim 5,
wherein the one or more first ground electrodes further include a fourth ground electrode, and
when viewed in the up-down direction, the distance between the first signal electrode and the first branch electrode is shorter than a distance between the first signal electrode and the fourth ground electrode, and a distance between the first branch electrode and the fourth ground electrode.

7. The circuit module according to claim 1,
wherein the first circuit board further includes an open stub conductor layer electrically connected to the first signal conductor layer or the first branch conductor layer, and
the open stub conductor layer is not electrically connected to an electrode other than an electrode to which the first signal conductor layer is electrically connected.

8. The circuit module according to claim 1,
wherein the one or more circuit boards include a second circuit board,
the second circuit board includes a second board body having a second upper main surface and a second lower main surface,
the first branch electrode is located on the first lower main surface,
the second branch electrode is located on the second upper main surface,
the first circuit board further includes
one or more second branch conductor layers provided in the first board body and electrically connected to the first signal conductor layer, and
one or more third branch electrodes located on the first lower main surface,
the second circuit board further includes one or more fourth branch electrodes located on the second upper main surface,
the one or more third branch electrodes are electrically connected to the one or more second branch conductor layers, and
the one or more fourth branch electrodes are electrically connected to the second ground conductor layer and are bonded to the one or more third branch electrodes by using a conductive bonding material.

9. The circuit module according to claim 1,
wherein a line width of a part of the first signal conductor layer is different from a line width of a remaining part of the first signal conductor layer when viewed in the up-down direction.

10. The circuit module according to claim 1,
wherein a line width of a part of the first branch conductor layer is different from a line width of a remaining part of the first branch conductor layer when viewed in the up-down direction.

11. The circuit module according to claim 10,
wherein the one or more circuit boards include a second circuit board,
the second circuit board includes a second board body having a second upper main surface and a second lower main surface,
the first branch electrode is located on the first lower main surface,
the second branch electrode is located on the second upper main surface, and
a thickness of the first board body in the up-down direction is smaller than a thickness of the second board body in the up-down direction.

12. The circuit module according to claim 10,
wherein the first board body has a structure in which a plurality of first dielectric layers are laminated in the up-down direction,
the second board body has a structure in which a plurality of second dielectric layers are laminated in the up-down direction,
the plurality of second dielectric layers include one or more third dielectric layers, and
a dielectric constant of the third dielectric layer is higher than dielectric constants of the plurality of first dielectric layers and dielectric constants of dielectric layers excluding the third dielectric layer among the plurality of second dielectric layers.

13. The circuit module according to claim 1,
wherein the first circuit board further includes an antenna provided in the first board body and electrically connected to the first signal conductor layer.

14. The circuit module according to claim 13,
wherein the one or more circuit boards include a second circuit board,
the second circuit board includes a second board body having a second upper main surface and a second lower main surface,
the first branch electrode is located on the first lower main surface,
the second branch electrode is located on the second upper main surface, and
a thickness of the second board body in the up-down direction is smaller than a thickness of the first board body in the up-down direction.

15. The circuit module according to claim 13,
wherein the one or more circuit boards include a second circuit board,
the second circuit board includes a second board body having a second upper main surface and a second lower main surface,
the first branch electrode is located on the first lower main surface,
the second branch electrode is located on the second upper main surface,
the first board body has a structure in which a plurality of first dielectric layers are laminated in the up-down direction,
the second board body has a structure in which a plurality of second dielectric layers are laminated in the up-down direction,
the plurality of first dielectric layers include one or more fourth dielectric layers, and
a dielectric constant of the fourth dielectric layer is higher than dielectric constants of dielectric layers excluding the fourth dielectric layer among the plurality of first dielectric layers and dielectric constants of the plurality of second dielectric layers.

16. The circuit module according to claim 13,
wherein the first circuit board further includes a third ground conductor layer provided in the first board body, and
the third ground conductor layer overlaps the first signal conductor layer when viewed in the up-down direction and overlaps the first signal electrode and the first branch electrode when viewed in the up-down direction.

17. The circuit module according to claim 1,
wherein the one or more circuit boards include a second circuit board,
the second circuit board includes a second board body having a second upper main surface and a second lower main surface,
the first branch electrode is located on the first lower main surface,
the second branch electrode is located on the second upper main surface,
the first board body includes a first protective layer laminated at a lowermost part in the first board body,
the second board body includes a second protective layer laminated at an uppermost part in the first board body,
the first signal electrode and the first branch electrode are exposed to an outside of the first board body through an opening provided in the first protective layer, and
the second signal electrode and the second branch electrode are exposed to an outside of the second board body through an opening provided in the second protective layer.

18. The circuit module according to claim 17,
wherein the first circuit board further includes a first ground conductor layer provided in the first board body and provided at the same position as the first branch electrode in the up-down direction,
the first ground conductor layer surrounds the first branch electrode when viewed in the up-down direction,
a part of the first ground conductor layer is exposed to the outside of the first board body along with the first branch electrode through the opening provided in the first protective layer, and
a part of the first ground conductor layer is bonded to the second branch electrode along with the first branch electrode by using a conductive bonding material.

19. The circuit module according to claim 2,
wherein the one or more circuit boards include a second circuit board,
the second circuit board includes a second board body having a second upper main surface and a second lower main surface,
the first branch electrode is located on the first lower main surface,
the second branch electrode is located on the second upper main surface,
the first circuit board further includes a fifth branch electrode located on the first lower main surface and electrically connected to the first ground conductor layer,
the second circuit board further includes
a third branch conductor layer provided in the second board body and electrically connected to the second signal conductor layer, and
a sixth branch electrode located on the second upper main surface and electrically connected to the third branch conductor layer, and
the sixth branch electrode is bonded to the fifth branch electrode by using a conductive bonding material.

20. The circuit module according to claim 1,
wherein the first board body has flexibility,
the first board body has a first section and a second section,
the up-down direction in the first section is defined as a Z-axis direction, and
the second section is bent in the Z-axis direction with respect to the first section.
